(19) United States
(12) Patent Application Publication
(10) Pub. No.: US 2026/0241614 A1
(43) Pub. Date: Aug. 20, 2026

(54) PATTERN FORMING METHOD AND ARTICLE MANUFACTURING METHOD

(71) Applicant: CANON KABUSHIKI KAISHA, Tokyo (JP)

(72) Inventors: MASANOBU OOTSUKA, Tokyo (JP); TOSHIKI ITO, Kanagawa (JP)

(21) Appl. No.: 19/539,250

(22) Filed: Feb. 13, 2026

(30) Foreign Application Priority Data
Feb. 18, 2025 (JP) 2025-024486

(51) Int. Cl. B29C 33/42

(52) U.S. Cl. CPC B29C 33/424

(57) ABSTRACT

A pattern forming method including forming an adhesion layer on a substrate using a vapor phase coating method, arranging a curable composition (A) containing a polymerizable compound (a) on the adhesion layer formed on the substrate, bringing the curable composition (A) into contact with a mold, curing the curable composition (A) to form a cured film, and separating the curable composition (A) and the mold from each other, wherein in the same space where cleanness is not less than 0.01 μm and a total amount of particles is not more than 10 pieces/m³, steps from the forming the adhesion layer to the separating are continuously executed.

### BACKGROUND

### Field of the Technology

The present disclosure relates to a pattern forming method and an article manufacturing method.

### Description of the Related Art

For semiconductor devices and MEMS, requirements of miniaturization are increasing, and as a micropatterning technique, an imprint technique (optical imprint technique) has received a great deal of attention as a microfabrication technique. In the imprint technique, a curable composition is cured in a state in which a mold with a fine concave-convex pattern formed on the surface is in contact with the curable composition supplied (applied) onto a substrate. Thus, the pattern of the mold is transferred to the cured film of the curable composition, thereby forming the pattern on the substrate. According to the imprint technique, it is possible to form, on a substrate, a fine pattern (structure) on the order of several nanometers (see Japanese Patent No. 6584578).

An example of a pattern forming method using the imprint technique will be described. First, a curable composition in liquid form is discretely dropped (arranged), using an inkjet method, in a pattern formation region on a substrate. The droplets of the curable composition arranged in the pattern formation region spread on the substrate. This phenomenon is called pre-spreading. Next, a mold is brought into contact with (pressed against) the curable composition on the substrate. Thus, the droplets of the curable composition spread to the whole region of the gap between the substrate and the mold in a direction parallel to the substrate surface by a capillary phenomenon. This phenomenon is called spreading. Also, by the capillary phenomenon, the curable composition fills concave portions that form the pattern of the mold. This phenomenon is called filling. Note that the time until spreading and filling are completed is called a filling time. If the filling of the curable composition is completed, the curable composition is irradiated with light to cure the curable composition. Then, the mold is released from the cured curable composition on the substrate. By executing these steps, the pattern of the mold is transferred to the curable composition on the substrate, and the pattern of a cured film of the curable composition is formed.

When processing a substrate using a pattern obtained using the imprint technique as a mask, a step called an inversion process can be applied. Japanese Patent Laid-Open No. 2016-162862 discloses the following inversion process step. An inversion layer is formed on a concave-convex pattern (inversion layer forming step), and an inversion layer material is buried in concave portions. The inversion layer material is stacked on the upper portions of convex portions of the concave-convex pattern as well to form an excess inversion layer. The excess inversion layer is removed (excess inversion layer removing step) to expose the top surface of the convex portion of the concave-convex pattern of the cured film of the curable composition, thereby exposing the inversion layer buried in the concave portions. The residual film of the concave-convex pattern and a carbon-based material layer that is a lower layer are etched using the exposed inversion layer as a mask, thereby forming an inversion pattern (lower layer etching step). In this specification, the residual film is the cured film remaining between the substrate and concave portions of the cured film of the curable composition (convex portions of a mold pattern).

In the conventional inversion process, a layer such as a spin-on-carbon (SOC) layer whose dry etching resistance is higher than that of the curable composition needs to be formed under the curable composition for imprint. Also, for the purpose of improving the adhesion between the SOC layer and the curable composition, an adhesion layer forming composition needs to be formed on the SOC layer as needed.

Also, in the conventional inversion process, the residual film of the curable composition with a low dry etching resistance needs to be minimized. The SOC layer and the adhesion layer are applied to a base material by a spin coating method. Foreign substances estimated to be derived mainly from the rotation driving unit of a spin coating apparatus are sandwiched between a mold and the lower layer, resulting in mold breakage.

### SUMMARY

The present disclosure has been made in consideration of the problem of the prior art, and provides a new technique concerning a pattern forming method and an article manufacturing method.

The present disclosure in one aspect provides a pattern forming method including forming an adhesion layer on a substrate using a vapor phase coating method, after the forming the adhesion layer, arranging a curable composition (A) containing a polymerizable compound (a) on the adhesion layer formed on the substrate, after the arranging, bringing the curable composition (A) on the substrate into contact with a mold with a concave-convex pattern, in which a thickness of a residual film sandwiched between a most projecting portion of the mold and the substrate is not less than 50 nm and a height difference of the concave-convex pattern of the mold is not more than the thickness of the residual film, after the bringing the curable composition into contact with the mold, curing the curable composition (A) to form a cured film, after the curing, separating the curable composition (A) and the mold from each other, after the separating, forming an inversion layer on the concave-convex pattern transferred from the mold onto the cured film, after the forming the inversion layer, removing an upper layer portion of the inversion layer such that a top surface of a convex portion of the concave-convex pattern is exposed in a state in which the inversion layer is buried in a concave portion of the concave-convex pattern, and after the removing, etching the cured film up to a surface of the substrate to form an inversion pattern using the inversion layer buried in the concave portion as a mask, wherein in the same space where cleanness is not less than 0.01 μm and a total amount of particles is not more than 10 pieces/m³, steps from the forming the adhesion layer to the separating are continuously executed.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a view for explaining a pattern forming method;

FIG. 2 is a view for explaining the breakage behavior of a mold pattern by a foreign substance;

FIG. 3 is a view for explaining an inversion process; and

FIG. 4 is a view showing an example of the configuration of an imprint apparatus.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

As a result of earnest examinations, the present inventors found an inversion process that does not need a spin coating process that may cause foreign substance contamination in a preprocess of stamping using a mold in an imprint technique and does not need an SOC layer. The present inventors also found that in the inversion process, the possibility of mold pattern breakage caused by a foreign substance unintentionally sandwiched between the mold and the substrate is low.

### Adhesion Layer Forming Composition

An adhesion layer forming composition (Z) according to the present disclosure contains a component consisting of a polyfunctional component that makes at least an adhesion primer layer formed by covalent bonding to a substrate using a vapor phase coating method and a liquid curable composition covalently bond to each other.

Examples of the component are alkoxysilane acrylates, halogenated silane acrylates, alkoxyvinylsilanes, mercaptoalkoxysilanes, and halogenated isocyanates. In an example, the polyfunctional component can be a component selected from alkoxysilane, vinylsilane, thiolsilane, and halogen alkyl alkoxysilane. Also, the functional group of the polyfunctional component is, for example, an isocyanate group.

Practical examples of polyfunctional alkoxysilane acrylates are compounds (1) and (2) to be described below. Examples of commercially available products are product code SIA0182.0 and product code SIA0200.0 manufactured by GELEST, but the products are not limited to these examples.

A terminal alkoxysilane such as 1,2-bis(trimethoxysilyl)ethane may be added as needed.

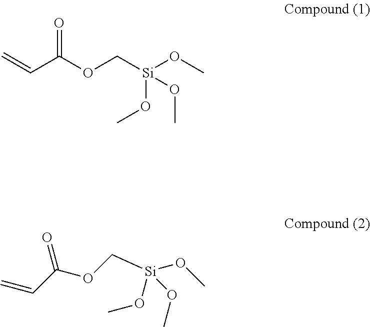

A practical example of polyfunctional halogenated silane acrylates is compound (3) to be described below. An example of commercially available products is product code SIA0199.0 manufactured by GELEST, but the product is not limited to this example. A terminal halogenated silane such as 1,6-bis(trichlorosilyl)hexane may be added as needed.

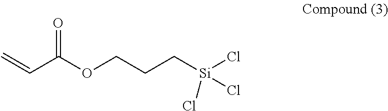

Practical examples of polyfunctional alkoxyvinylsilanes are compounds (4) to (8) to be described below.

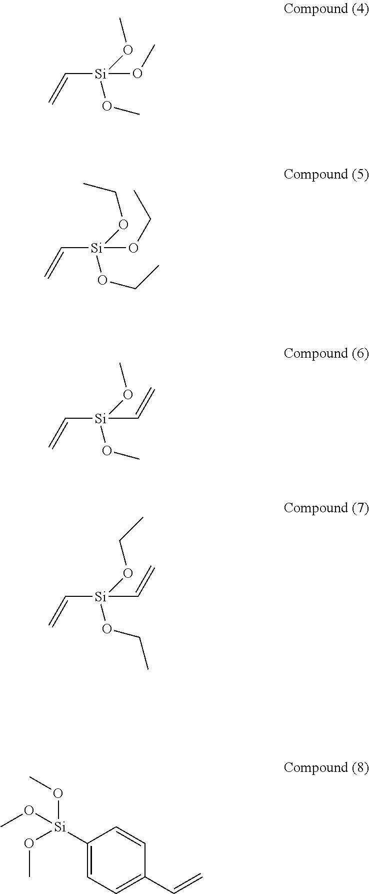

Examples of commercially available products are product code SIV9220.0 Sila-Ace S210 and product code SIV9112.0 Sila-Ace S220 manufactured by GELEST, but the products are not limited to these examples.

Examples of mercaptoalkoxysilanes are 3-mercaptopropyl(dimethoxy)methylsilane, (3-mercaptopropyl)trimethoxysilane, 1-(dimethoxymethylsilyl)methanethiol, 1-(trimethoxysilyl)methanethiol, 2-(dimethoxymethylsilyl)ethanethiol, and 2-(trimethoxysilyl)ethanethiol.

An example of commercially available products is product code SIA6476.0 Sila-Ace S810 manufactured by GELEST, but the product is not limited to this example.

Practical examples of polyfunctional halogenated isocyanates are 1-chloro-3-isocyanatobenzene, 1-bromo-4-isocyanatobenzene, 1,3-dichloro-5-isocyanatobenzene, 3,3′-dichloro-4,4′-diisocyanato-1,1′-biphenyl, 1-chloro-2-isocyanatoethane, 1-fluoro-3-isocyanatobenzene, and 1-chloro-4-isocyanato-2-(trifluoromethyl)benzene, but the polyfunctional halogenated isocyanates are not limited to these examples.

Other examples of polyfunctional isocyanates are p-isopropenyl-α, α-dimethylbenzyl isocyanate, and 2-isocyanate ethyl methacrylate, but the polyfunctional isocyanates are not limited to these examples.

The boiling point of the polyfunctional component that makes at least the adhesion primer layer formed by covalent bonding to the substrate using the vapor phase coating method and the liquid curable composition covalently bond to each other is preferably 350° C. or less. The boiling point is preferably 200° C. or less and more preferably 80° C. or less from the viewpoint of energy saving. In addition, the viscosity of the polyfunctional component is preferably 100 mPa·s or less. The viscosity is preferably 50 mPa·s or less and more preferably 10 mPa·s or less from the viewpoint of handling.

### [Curable Composition]

A curable composition (A) according to the present disclosure is a composition containing at least a component (a) as a polymerizable compound, and a component (b) as a photopolymerization initiator. The curable composition (A) according to the present disclosure may further contain a nonpolymerizable compound (c), and a component (d) as a solvent.

In this specification, a cured film means a film cured by polymerizing the curable composition (A) on a substrate. Note that the cured film has a pattern shape on the surface.

### <Component (a): Polymerizable Compound>

The component (a) is a polymerizable compound. In this specification, the polymerizable compound is a compound that reacts with a polymerizing factor (for example, a radical) generated from a polymerization initiator (the component (b)), and forms a film made of a polymer compound by a chain reaction (polymerization reaction).

An example of the polymerizable compound as described above is a radical polymerizable compound. The polymerizable compound as the component (a) can be formed by only one type of a polymerizable compound, and can also be formed by a plurality of types of polymerizable compounds.

Examples of the radical polymerizable compound are a (meth)acrylic compound, a styrene-based compound, a vinyl-based compound, an allylic compound, a fumaric compound, and a maleic compound. The (meth)acrylic compound is a compound having one or more acryloyl groups or methacryloyl groups. Examples of a monofunctional (meth)acrylic compound having one acryloyl group or methacryloyl group are as follows, but the compound is not limited to these examples.

Phenoxyethyl (meth)acrylate, phenoxy-2-methylethyl (meth)acrylate, phenoxyethoxyethyl (meth)acrylate, 3-phenoxy-2-hydroxypropyl (meth)acrylate, 2-phenylphenoxyethyl (meth)acrylate, 4-phenylphenoxyethyl (meth)acrylate, 3-(2-phenylphenyl)-2-hydroxypropyl (meth)acrylate, (meth)acrylate of EO-modified p-cumylphenol, 2-bromophenoxyethyl (meth)acrylate, 2,4-dibromophenoxyethyl (meth)acrylate, 2,4,6-tribromophenoxyethyl (meth)acrylate, EO-modified phenoxy (meth)acrylate, PO-modified phenoxy (meth)acrylate, polyoxyethylenenonylphenylether (meth)acrylate, isobornyl (meth)acrylate, 1-adamantyl (meth)acrylate, 2-methyl-2-adamantyl (meth)acrylate, 2-ethyl-2-adamantyl (meth)acrylate, bornyl (meth)acrylate, tricyclodecanyl (meth)acrylate, dicyclopentanyl (meth)acrylate, dicyclopentenyl (meth)acrylate, cyclohexyl (meth)acrylate, 4-butylcyclohexyl (meth)acrylate, acryloylmorpholine, 2-hydroxyethyl (meth)acrylate, 2-hydroxypropyl (meth)acrylate, 2-hydroxybutyl (meth)acrylate, methyl (meth)acrylate, ethyl (meth)acrylate, propyl (meth)acrylate, isopropyl (meth)acrylate, butyl (meth)acrylate, amyl (meth)acrylate, isobutyl (meth)acrylate, t-butyl (meth)acrylate, pentyl (meth)acrylate, isoamyl (meth)acrylate, hexyl (meth)acrylate, heptyl (meth)acrylate, octyl (meth)acrylate, isooctyl (meth)acrylate, 2-ethylhexyl (meth)acrylate, nonyl (meth)acrylate, decyl (meth)acrylate, isodecyl (meth)acrylate, undecyl (meth)acrylate, dodecyl (meth)acrylate, lauryl (meth)acrylate, stearyl (meth)acrylate, isostearyl (meth)acrylate, benzyl (meth)acrylate, tetrahydrofurfuryl (meth)acrylate, butoxyethyl (meth)acrylate, ethoxydiethyleneglycol (meth)acrylate, polyethyleneglycol mono(meth)acrylate, polypropyleneglycol mono(meth)acrylate, methoxyethyleneglycol (meth)acrylate, ethoxyethyl (meth)acrylate, methoxypolyethyleneglycol (meth)acrylate, methoxypolypropyleneglycol (meth)acrylate, diacetone (meth)acrylamide, isobutoxymethyl (meth)acrylamide, N,N-dimethyl (meth)acrylamide, t-octyl (meth)acrylamide, dimethylaminoethyl (meth)acrylate, diethylaminoethyl (meth)acrylate, 7-amino-3,7-dimethyloctyl (meth)acrylate, N,N-diethyl (meth)acrylamide, N,N-dimethylaminopropyl (meth)acrylamide, 1- or 2-naphthyl (meth)acrylate, 1- or 2-naphthylmethyl (meth)acrylate, 3- or 4-phenoxybenzyl (meth)acrylate, and cyanobenzyl (meth)acrylate.

Examples of commercially available products of the above-described monofunctional (meth)acrylic compounds are as follows, but the products are not limited to these examples.

ARONIX® M101, M102, M110, M111, M113, M117, M5700, TO-1317, M120, M150, and M156 (manufactured by TOAGOSEI); MEDOL10, MIBDOL10, CHDOL10, MMDOL30, MEDOL30, MIBDOL30, CHDOL30, LA, IBXA, 2-MTA, HPA, and Viscoat #150, #155, #158, #190, #192, #193, #220, #2000, #2100, and #2150 (manufactured by OSAKA ORGANIC CHEMICAL INDUSTRY); Light Acrylate BO-A, EC-A, DMP-A, THF-A, HOP-A, HOA-MPE, HOA-MPL, PO-A, P-200A, NP-4EA, NP-8EA, Epoxy Ester M-600A, POB-A, and OPP-EA (manufactured by KYOEISHA CHEMICAL); KAYARAD® TC110S, R-564, and R-128H (manufactured by NIPPON KAYAKU); NK Ester AMP-10G, AMP-20G, and A-LEN-10 (manufactured by SHIN-NAKAMURA CHEMICAL); FA-511A, 512A, and 513A (manufactured by Hitachi Chemical); PHE, CEA, PHE-2, PHE-4, BR-31, BR-31M, and BR-32 (manufactured by DKS); VP (manufactured by BASF); and ACMO, DMAA, and DMAPAA (manufactured by Kohjin).

Examples of a polyfunctional (meth)acrylic compound having two or more acryloyl groups or methacryloyl groups are as follows, but the compound is not limited to these examples.

Trimethylolpropane di(meth)acrylate, trimethylolpropane tri(meth)acrylate, EO-modified trimethylolpropane tri(meth)acrylate, PO-modified trimethylolpropane tri(meth)acrylate, EO- and PO-modified trimethylolpropane tri(meth)acrylate, dimethylol tricyclodecane di(meth)acrylate, pentaerythritol tri(meth)acrylate, pentaerythritol tetra(meth)acrylate, ethylene glycol di(meth)acrylate, tetraethylene glycol di(meth)acrylate, polyethylene glycol di(meth)acrylate, polypropylene glycol di(meth)acrylate, 1,4-butanediol di(meth)acrylate, 1,6-hexanediol di(meth)acrylate, neopentyl glycol di(meth)acrylate, 1,9-nonanediol di(meth)acrylate, 1,10-decanediol di(meth)acrylate, 1,3-adamantanedimethanol di(meth)acrylate, tris(2-hydroxyethyl)isocyanurate tri(meth)acrylate, tris(acryloyloxy)isocyanurate, bis(hydroxymethyl)tricyclodecane di(meth)acrylate, dipentaerythritol penta(meth)acrylate, dipentaerythritol hexa(meth)acrylate, EO-modified 2,2-bis(4-((meth)acryloxy)phenyl)propane, PO-modified 2,2-bis(4-((meth)acryloxy)phenyl)propane, EO- and PO-modified 2,2-bis(4-((meth)acryloxy)phenyl)propane, o-, m-, or p-benzene di(meth)acrylate, and o-, m-, or p-xylylene di(meth)acrylate.

Examples of commercially available products of the above-described polyfunctional (meth)acrylic compounds are as follows, but the products are not limited to these examples.

Yupimer® UV SA1002 and SA2007 (manufactured by Mitsubishi Chemical); Viscoat #195, #230, #215, #260, #335HP, #295, #300, #360, #700, GPT, and 3PA (manufactured by OSAKA ORGANIC CHEMICAL INDUSTRY); Light Acrylate 4EG-A, 9EG-A, NP-A, DCP-A, BP-4EA, BP-4PA, TMP-A, PE-3A, PE-4A, and DPE-6A (manufactured by KYOEISHA CHEMICAL); KAYARAD® PET-30, TMPTA, R-604, DPHA, DPCA-20, -30, -60, and -120, HX-620, D-310, and D-330 (manufactured by NIPPON KAYAKU); ARONIX® M208, M210, M215, M220, M240, M305, M309, M310, M315, M325, and M400 (manufactured by TOAGOSEI); Ripoxy® VR-77, VR-60, and VR-90 (manufactured by Showa Highpolymer); and OGSOL EA-0200 and OGSOL EA-0300 (manufactured by Osaka Gas Chemicals).

Note that in the above-described compound group, (meth)acrylate means acrylate or methacrylate having an alcohol residue equal to acrylate. A (meth)acryloyl group means an acryloyl group or a methacryloyl group having an alcohol residue equal to the acryloyl group. EO indicates ethylene oxide, and an EO-modified compound A indicates a compound in which a (meth)acrylic acid residue and an alcohol residue of a compound A bond via the block structure of an ethylene oxide group. Also, PO indicates a propylene oxide, and a PO-modified compound B indicates a compound in which a (meth)acrylic acid residue and an alcohol residue of a compound B bond via the block structure of a propylene oxide group.

Practical examples of the styrene-based compound are as follows, but the compound is not limited to these examples.

Alkylstyrene such as styrene, 2,4-dimethyl-α-methylstyrene, o-methylstyrene, m-methylstyrene, p-methylstyrene, 2,4-dimethylstyrene, 2,5-dimethylstyrene, 2,6-dimethylstyrene, 3,4-dimethylstyrene, 3,5-dimethylstyrene, 2,4,6-trimethylstyrene, 2,4,5-trimethylstyrene, pentamethylstyrene, o-ethylstyrene, m-ethylstyrene, p-ethylstyrene, diethylstyrene, triethylstyrene, propylstyrene 2,4-diisopropylstyrene, butylstyrene, hexylstyrene, heptylstyrene, and octylstyrene; styrene halide such as fluorostyrene, o-chlorostyrene, m-chlorostyrene, p-chlorostyrene, o-bromostyrene, m-bromostyrene, p-bromostyrene, dibromostyrene, and iodostyrene; and a compound having a styryl group as a polymerizable functional group, such as nitrostyrene, acetylstyrene, o-methoxystyrene, m-methoxystyrene, p-methoxystyrene, o-hydroxystyrene, m-hydroxystyrene, p-hydroxystyrene, 2-vinylbiphenyl, 3-vinylbiphenyl, 4-vinylbiphenyl, 1-vinylnaphthalene, 2-vinylnaphthalene, 4-vinyl-p-terphenyl, 1-vinylanthracene, α-methylstyrene, o-isopropenyltoluene, m-isopropenyltoluene, p-isopropenyltoluene, 2,3-dimethyl-α-methylstyrene, 3,5-dimethyl-α-methylstyrene, p-isopropyl-α-methylstyrene, α-ethylstyrene, α-chlorostyrene, divinylbenzene, diisopropylbenzene, and divinylbiphenyl.

Practical examples of the vinyl-based compound are as follows, but the compound is not limited to these examples.

Vinylpyridine, vinylpyrrolidone, vinylcarbazole, vinyl acetate, and acrylonitrile; conjugated diene monomers such as butadiene, isoprene, and chloroprene; vinyl halide such as vinyl chloride and vinyl bromide; a compound having a vinyl group as a polymerizable functional group, for example, vinylidene halide such as vinylidene chloride, vinyl ester of organic carboxylic acid and its derivative (for example, vinyl acetate, vinyl propionate, vinyl butyrate, vinyl benzoate, and divinyl adipate), and (meth)acrylonitrile.

Note that in this specification, (meth)acrylonitrile is a general term for acrylonitrile and methacrylonitrile.

Examples of the allylic compound are as follows, but the compound is not limited to these examples.

Allyl acetate, allyl benzoate, diallyl adipate, diallyl terephthalate, diallyl isophthalate, and diallyl phthalate.

Examples of the fumaric compound are as follows, but the compound is not limited to these examples.

Dimethyl fumarate, diethyl fumarate, diisopropyl fumarate, di-sec-butyl fumarate, diisobutyl fumarate, di-n-butyl fumarate, di-2-ethylhexyl fumarate, and dibenzyl fumarate.

Examples of the maleic compound are as follows, but the compound is not limited to these examples.

Dimethyl maleate, diethyl maleate, diisopropyl maleate, di-sec-butyl maleate, diisobutyl maleate, di-n-butyl maleate, di-2-ethylhexyl maleate, and dibenzyl maleate.

Other examples of the radical polymerizable compound are as follows, but the compound is not limited to these examples.

Dialkylester of itaconic acid and its derivative (for example, dimethyl itaconate, diethyl itaconate, diisopropyl itaconate, di-sec-butyl itaconate, diisobutyl itaconate, di-n-butyl itaconate, di-2-ethylhexyl itaconate, and dibenzyl itaconate), an N-vinylamide derivative of organic carboxylic acid (for example, N-methyl-N-vinylacetamide), and maleimide and its derivative (for example, N-phenylmaleimide and N-cyclohexylmaleimide).

If the component (a) is formed by a plurality of types of compounds having one or more polymerizable functional groups, a monofunctional compound and a polyfunctional compound are preferably included. This is because if a monofunctional compound and a polyfunctional compound are combined, a cured film having well-balanced performance, for example, a high mechanical strength, a high dry etching resistance, and a high heat resistance can be obtained.

The polymerizable compound (a) preferably has low volatility. Hence, in the polymerizable compound (a) that can contain a plurality of types of compounds, the boiling points of all the compounds at normal pressure are preferably 250° C. or more, more preferably 300° C. or more, and further preferably 350° C. or more. The boiling point of the polymerizable compound (a) is basically correlated with the molecular weight. Therefore, the molecular weights of all the polymerizable compounds (a) are preferably 200 or more, more preferably 240 or more, and further preferably 250 or more. However, even when the molecular weight is 200 or less, the compound is preferably usable as the polymerizable compound (a) of the present disclosure if the boiling point is 250° C. or more.

In addition, the vapor pressure at 80° C. of the polymerizable compound (a) is preferably 0.001 mmHg or less. This is so because, although it is favorable to heat the curable composition when accelerating volatilization of the solvent (d) (to be described later), it is necessary to suppress volatilization of the polymerizable compound (a) during heating.

Note that the boiling point and the vapor pressure of each organic compound at normal pressure can be calculated by, for example, Hansen Solubility Parameters in Practice (HSPiP) 5th Edition. 5.3.04.

<Ohnishi Parameter (OP) of Component (a)>

It is known that a dry etching rate V of an organic compound, a number N of all atoms in the organic compound, a number N_{C} of all carbon atoms in a composition, and a number N_{O} of all oxygen atoms in the composition have a relationship of equation (1) below (NPL 1) (see J. Electrochem. Soc., 130, p. 143 (1983)).

$$V ∝ N / ( {N}_{C} - {N}_{o} ) \qquad ( 1 )$$

where N/(N_{C}−N_{O}) is also called “Ohnishi Parameter” (to be referred to as “OP” hereinafter). For example, Japanese Patent Laid-Open No. 2016-162862 describes a technique of obtaining a photocurable composition having a high dry etching resistance by using a polymerizable compound having a small OP.

Equation (1) indicates that an organic compound having many oxygen atoms in a molecule or having few aromatic ring structures or alicyclic structures has a large OP and a high dry etching rate.

In the present disclosure, the OP of the component (a) is preferably 2.00 or more and 3.00 or less, more preferably 2.00 or more and 2.80 or less, and particularly preferably 2.00 or more and 2.60 or less. When the OP is 3.00 or less, the cured film of the curable composition (A) has a high dry etching resistance. Also, when the OP is 2.00 or more, the cured film of the curable composition (A) can easily be removed when the underlayer is processed by using the cured film of the curable composition (A). When the component (a) is formed by a plurality of types of polymerizable compounds a₁, a₂, . . . , aₙ, the OP is calculated as a weighted average value (molar fraction weighted average value) based on the molar fraction as indicated by equation (2) below:

$$OP = {\sum }_{i = n} {n}_{i} {OP}_{i} = {n}_{1} {OP}_{1} + {n}_{2} {OP}_{2} + … + {n}_{n} {OP}_{n} \qquad ( 2 )$$

where OPₙ is the OP of the component aₙ, and nₙ is the molar fraction occupied by the component aₙ in the entire component (a).

To set the OP of the component (a) to 2.00 or more and 3.00 or less, a compound having a cyclic structure such as an aromatic structure, an aromatic heterocyclic structure, or an alicyclic structure is preferably contained at least as the component (a).

The carbon number of the aromatic structure is preferably 6 to 22, more preferably 6 to 18, and further preferably 6 to 10. Practical examples of the aromatic ring are as follows.

A benzene ring, a naphthalene ring, an anthracene ring, a phenanthrene ring, a phenalene ring, a fluorene ring, a benzocyclooctene ring, an acenaphthylene ring, a biphenylene ring, an indene ring, an indane ring, a triphenylene ring, a pyrene ring, a chrysene ring, a perylene ring, and a tetrahydronaphthalene ring.

Note that, of the above-described aromatic rings, a benzene ring or a naphthalene ring is preferable, and a benzene ring is more preferable. The aromatic ring can have a structure in which a plurality of rings are connected. Examples are a biphenyl ring and a bisphenyl ring.

The carbon number of the aromatic heterocyclic structure is preferably 1 to 12, more preferably 1 to 6, and further preferably 1 to 5. Practical examples of the aromatic heterocycle are as follows.

A thiophene ring, a furan ring, a pyrrole ring, an imidazole ring, a pyrazole ring, a triazole ring, a tetrazole ring, a thiazole ring, a thiadiazole ring, an oxadiazole ring, an oxazole ring, a pyridine ring, a pyrazine ring, a pyrimidine ring, pyridazine ring, an isoindole ring, an indole ring, an indazole ring, a purine ring, a quinolizine ring, an isoquinoline ring, a quinoline ring, a phthalazine ring, a naphthyridine ring, a quinoxaline ring, a quinazoline ring, a cinnoline ring, a carbazole ring, an acridine ring, a phenazine ring, a phenothiazine ring, a phenoxathiine ring, and a phenoxazine ring.

The carbon number of the alicyclic structure is preferably 3 or more, more preferably 4 or more, and further preferably 6 or more. In addition, the carbon number of the alicyclic structure is preferably 22 or less, more preferably 18 or less, further preferably 6 or less, and still further preferably 5 or less. Practical examples are as follows.

A cyclopropane ring, a cyclobutane ring, a cyclobutene ring, a cyclopentane ring, a cyclohexane ring, a cyclohexene ring, a cycloheptane ring, a cyclooctane ring, a dicyclopentadiene ring, a spirodecane ring, a spirononane ring, a tetrahydrodicyclopentadiene ring, an octahydronaphthalene ring, a decahydronaphthalene ring, a hexahydroindane ring, a bornane ring, a norbornane ring, a norbornene ring, an isobornane ring, a tricyclodecane ring, a tetracyclododecane ring, and an adamantane ring.

Practical examples of the polymerizable compound (a) having a cyclic structure and a boiling point of 250° C. or more are as follows, but the compound is not limited to these examples.
dicyclopentanyl acrylate (boiling point=262° C., molecular weight=206)
dicyclopentenyl acrylate (boiling point=270° C., molecular weight=204)
1,3-cyclohexanedimethanol diacrylate (boiling point=310° C., molecular weight=252)
1,4-cyclohexanedimethanol diacrylate (boiling point=339° C., molecular weight=252)
4-hexylresorcinol diacrylate (boiling point=379° C., molecular weight=302)
6-phenylhexane-1,2-diol diacrylate (boiling point=381° C., molecular weight=302)
7-phenylheptan-1,2-diol diacrylate (boiling point=393° C., molecular weight=316)
1,3-bis((2-hydroxyethoxy)methyl)cyclohexane diacrylate (boiling point=403° C., molecular weight=340)
8-phenyloctane-1,2-diol diacrylate (boiling point=404° C., molecular weight=330)
1,3-bis((2-hydroxyethoxy)methyl)benzene diacrylate (boiling point=408° C., molecular weight=334)
1,4-bis((2-hydroxyethoxy)methyl)cyclohexane diacrylate (boiling point=445° C., molecular weight=340)
3-phenoxybenzyl acrylate (mPhOBzA, OP=2.54, boiling point=367.4° C., 80° C. vapor pressure=0.0004 mmHg, molecular weight=254.3)

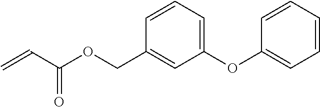 [SMILES: C=CC(=O)OCc1cccc(Oc2ccccc2)c1]

1-naphthyl acrylate (NaA, OP=2.27, boiling point=317° C., 80° C. vapor pressure=0.0422 mmHg, molecular weight=198)

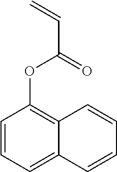

2-phenylphenoxyethyl acrylate (PhPhOEA, OP=2.57, boiling point=364.2° C., 80° C. vapor pressure=0.0006 mmHg, molecular weight=268.3)

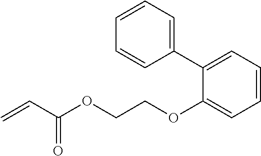 [SMILES: C=CC(=O)OCCOc1ccccc1-c1ccccc1]

1-naphthylmethyl acrylate (NalMA, OP=2.33, boiling point=342.1° C., 80° C. vapor pressure=0.042 mmHg, molecular weight=212.2)

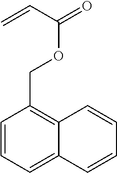 [SMILES: C=CC(=O)OCc1cccc2ccccc12]

2-naphthylmethyl acrylate (Na2MA, OP=2.33, boiling point=342.1° C., 80° C. vapor pressure=0.042 mmHg, molecular weight=212.2)

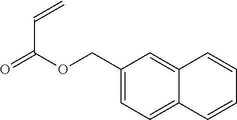 [SMILES: C=CC(=O)OCc1ccc2ccccc2c1]

4-cyanobenzyl acrylate (CNBzA, OP=2.44, boiling point=316° C., molecular weight=187)

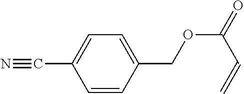

DVBzA indicated by the formula below (OP=2.50, boiling point=304.6° C., 80° C. vapor pressure=0.0848 mmHg, molecular weight=214.3)

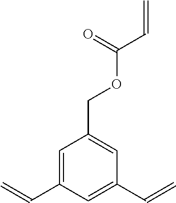 [SMILES: C=CC(=O)OCc1cc(C=C)cc(C=C)c1]

DPhPA indicated by the formula below (OP=2.38, boiling point=354.5° C., 80° C. vapor pressure=0.0022 mmHg, molecular weight=266.3)

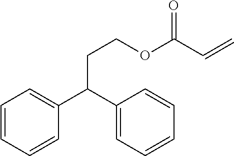 [SMILES: C=CC(=O)OCCC(c1ccccc1)c1ccccc1]

PhBzA indicated by the formula below (OP=2.29, boiling point=350.4° C., 80° C. vapor pressure=0.0022 mmHg, molecular weight=238.3)

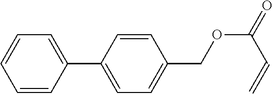 [SMILES: C=CC(=O)OCc1ccc(-c2ccccc2)cc1]

FLMA indicated by the formula below (OP=2.20, boiling point=349.3° C., 80° C. vapor pressure=0.0018 mmHg, molecular weight=250.3)

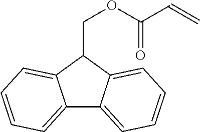 [SMILES: C=CC(=O)OCC1c2ccccc2-c2ccccc21]

ATMA indicated by the formula below (OP=2.13, boiling point=414.9° C., 80° C. vapor pressure=0.0001 mmHg, molecular weight=262.3)

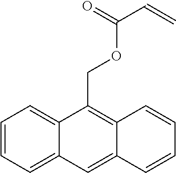 [SMILES: C=CC(=O)OCc1c2ccccc2cc2ccccc12]

DNaMA indicated by the formula below (OP=2.00, boiling point=489.4° C., 80° C. vapor pressure <0.0001 mmHg, molecular weight=338.4)

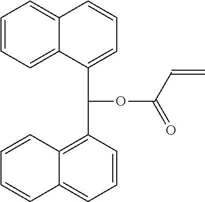 [SMILES: C=CC(=O)OC(c1cccc2ccccc12)c1cccc2ccccc12]

tricyclodecanedimethanol diacrylate (DCPDA, OP=3.29, boiling point=342° C., 80° C. vapor pressure <0.0024 mmHg, molecular weight=304)

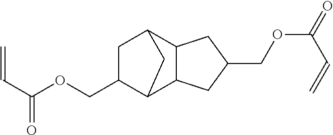 [SMILES: C=CC(=O)OCC1CC2C3CC(COC(=O)C=C)C(C3)C2C1]

m-xylylene diacrylate (mXDA, OP=3.20, boiling point=336° C., 80° C. vapor pressure <0.0043 mmHg, molecular weight=246)

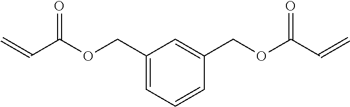 [SMILES: C=CC(=O)OCc1cccc(COC(=O)C=C)c1]

1-phenylethane-1,2-diyl diacrylate (PhEDA, OP=3.20, 80° C. vapor pressure <0.0057 mmHg, boiling point=354° C., molecular weight=246)

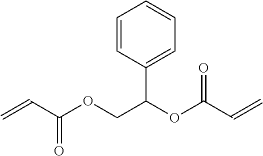 [SMILES: C=CC(=O)OCC(OC(=O)C=C)c1ccccc1]

2-phenyl-1,3-propane-diol diacrylate (PhPDA, OP=3.18, boiling point=340° C., 80° C. vapor pressure <0.0017 mmHg, molecular weight=260)

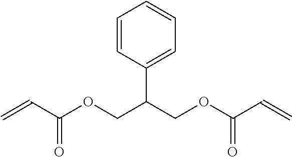 [SMILES: C=CC(=O)OCC(COC(=O)C=C)c1ccccc1]

VmXDA indicated by the formula below (OP=3.00, boiling point=372.4° C., 80° C. vapor pressure=0.0005 mmHg, molecular weight=272.3)

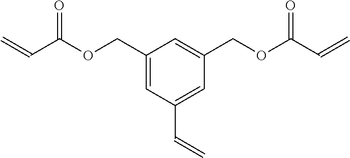 [SMILES: C=CC(=O)OCc1cc(C=C)cc(COC(=O)C=C)c1]

BPh44DA indicated by the formula below (OP=2.63, boiling point=444° C., 80° C. vapor pressure <0.0001 mmHg, molecular weight=322.3)

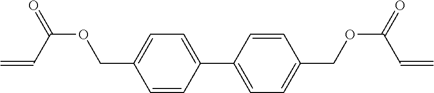 [SMILES: C=CC(=O)OCc1ccc(-c2ccc(COC(=O)C=C)cc2)cc1]

BPh43DA indicated by the formula below (OP=2.63, boiling point=439.5° C., 80° C. vapor pressure <0.0001 mmHg, molecular weight=322.3)

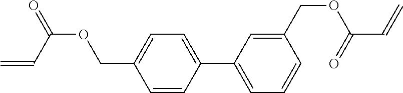 [SMILES: C=CC(=O)OCc1ccc(-c2cccc(COC(=O)C=C)c2)cc1]

DPhEDA indicated by the formula below (OP=2.63, boiling point=410° C., 80° C. vapor pressure <0.0001 mmHg, molecular weight=322.3)

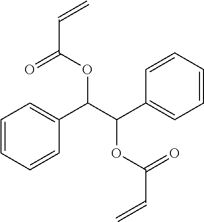 [SMILES: C=CC(=O)OC(c1ccccc1)C(OC(=O)C=C)c1ccccc1]

BPMDA indicated by the formula below (OP=2.68, boiling point=465.7° C., 80° C. vapor pressure <0.0001 mmHg, molecular weight=364.4)

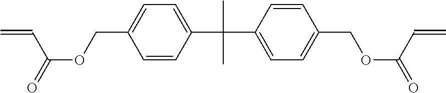 [SMILES: C=CC(=O)OCc1ccc(C(C)(C)c2ccc(COC(=O)C=C)cc2)cc1]

Na13MDA indicated by the formula below (OP=2.71, boiling point=438.8° C., 80° C. vapor pressure <0.0001 mmHg, molecular weight=296.3)

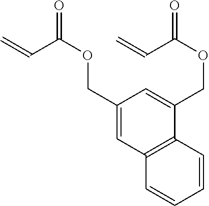 [SMILES: C=CC(=O)OCc1cc(COC(=O)C=C)c2ccccc2c1]

The blending ratio of the component (a) in the curable composition (A) is preferably 40 wt % or more and 99 wt % or less with respect to the sum of the component (a), a component (b) (to be described later), and a component (c) (to be described later), that is, the total mass of all the components except the solvent (d). The blending ratio is more preferably 50 wt % or more and 95 wt % or less, and further preferably 60 wt % or more and 90 wt % or less. When the blending ratio of the component (a) is 40 wt % or more, the mechanical strength of the cured film of the curable composition increases. Also, when the blending ratio of the component (a) is 99 wt % or less, it is possible to increase the blending ratios of the components (b) and (c), and obtain characteristics such as a high photopolymerization rate.

At least a part of the component (a) of the present disclosure, which may include a plurality of types of additive components, can be polymers having a polymerizable functional group. The polymer preferably contains at least a cyclic structure such as an aromatic structure, an aromatic heterocyclic structure, or an alicyclic structure. For example, the polymer preferably contains at least one of constituent units represented by formulas (1) to (6) below:

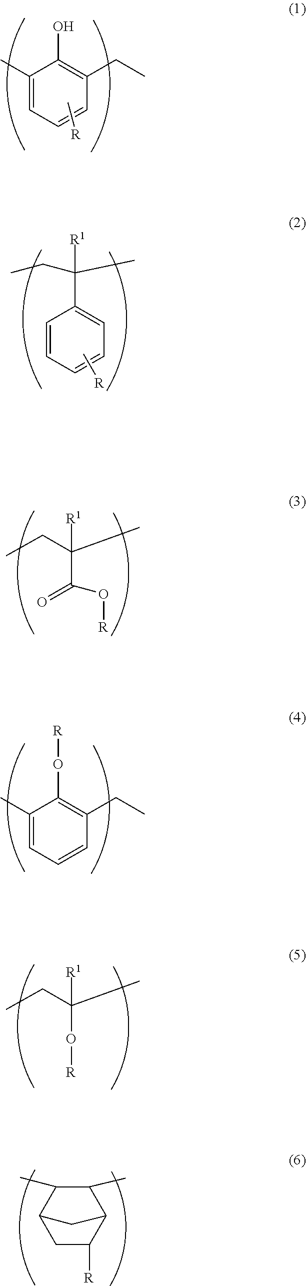

In the formulas (1) to (6), a substituent group R is a substituent group containing partial structures each independently containing an aromatic ring, and R1 is a hydrogen atom or a methyl group. In this specification, in constituent units represented by the formulas (1) to (6), a portion other than R is the main chain of a specific polymer. The formula weight of the substituent group R is 80 or more, preferably 100 or more, more preferably 130 or more, and further preferably 150 or more. The upper limit is practically 500 or less.

A polymer having a polymerizable functional group is normally a compound having a weight-average molecular weight of 500 or more. The weight-average molecular weight is preferably 1,000 or more, and more preferably 2,000 or more. The upper limit of the weight-average molecular weight is not particularly determined, but is preferably, for example, 50,000 or less. When the weight-average molecular weight is set at the above-described lower limit or more, it is possible to set the boiling point at 250° C. or more, and further improve the mechanical properties after curing. Also, when the weight-average molecular weight is set at the above-described upper limit or less, the solubility to the solvent increases, and the flowability of discretely arranged droplets is maintained because the viscosity is not too high. This makes it possible to further improve the flatness of the liquid film surface. Note that the weight-average molecular weight (Mw) in the present disclosure is a molecular weight measured by gel permeation chromatography (GPC).

Practical examples of the polymerizable functional group of the polymer are a (meth)acryloyl group, an epoxy group, an oxetane group, a methylol group, a methylol ether group, and a vinyl ether group. A (meth)acryloyl group is particularly favorable from the viewpoint of polymerization easiness.

When adding the polymer having the polymerizable functional group as at least a part of the component (a), the blending ratio can freely be set as long as the blending ratio falls within the range of the viscosity regulation to be described later. For example, the blending ratio of polymer to the total mass of all the components except for the solvent (d) is preferably 0.1 wt % or more and 60 wt % or less. The blending ratio is more preferably 1 wt % or more and 50 wt % or less, and further preferably 10 wt % or more and 40 wt % or less. When the blending ratio of the polymer having the polymerizable functional group is set at 0.1 wt % or more, it is possible to improve the dry etching resistance, the heat resistance, the mechanical strength, and the low volatility. Also, when the blending ratio is set at 60 wt % or less, it is possible to make the blending ratio fall within the range of the upper limit regulation of the viscosity (to be described later).

### <Component (b): Photopolymerization Initiator>

The component (b) is a photopolymerization initiator. In this specification, the photopolymerization initiator is a compound that senses light having a predetermined wavelength and generates a polymerization factor (radical) described earlier. More specifically, the photopolymerization initiator is a polymerization initiator (radical generator) that generates a radical by light (infrared light, visible light, ultraviolet light, far-ultraviolet light, X-ray, a charged particle beam such as an electron beam, or radiation).

The component (b) can be formed by only one type of a photopolymerization initiator, and can also be formed by a plurality of types of photopolymerization initiators.

Examples of the radical generator are as follows, but the radical generator is not limited to these examples.

2,4,5-triarylimidazole dimers that can have substituent groups, such as a 2-(o-chlorophenyl)-4,5-diphenylimidazole dimer, a 2-(o-chlorophenyl)-4,5-di(methoxyphenyl)imidazole dimer, a 2-(o-fluorophenyl)-4,5-diphenylimidazole dimer, and a 2-(o- or p-methoxyphenyl)-4,5-diphenylimidazole dimer; benzophenone derivatives such as benzophenone, N,N′-tetramethyl-4,4′-diaminobenzophenone (Michler's ketone), N,N′-tetraethyl-4,4′-diaminobenzophenone, 4-methoxy-4′-dimethylaminobenzophenone, 4-chlorobenzophenone, 4,4′-dimethoxybenzophenone, and 4,4′-diaminobenzophenone; α-amino aromatic ketone derivatives such as 2-benzyl-2-dimethylamino-1-(4-morpholinophenyl)-butanone-1,2-methyl-1-[4-(methylthio)phenyl]-2-morpholino-propane-1-one; quinones such as 2-ethylanthraquinone, phenanthrenequinone, 2-t-butylanthraquinone, octamethylanthraquinone, 1,2-benzanthraquinone, 2,3-benzanthraquinone, 2-phenylanthraquinone, 2,3-diphenylanthraquinone, 1-chloroanthraquinone, 2-methylanthraquinone, 1,4-napthoquinone, 9,10-phenanthraquinone, 2-methyl-1,4-napthoquinone, and 2,3-dimethylanthraquinone; benzoin ether derivatives such as benzoin methyl ether, benzoin ethyl ether, and benzoin phenyl ether; benzoin derivatives such as benzoin, methyl benzoin, ethyl benzoin, and propyl benzoin; benzyl derivatives such as benzyldimethylketal; acridine derivatives such as 9-phenylacridine and 1,7-bis(9,9′-acrydinyl)heptane; N-phenylglycine derivatives such as N-phenylglycine; acetophenone derivatives such as acetophenone, 3-methylacetophenone, acetophenone benzylketal, 1-hydroxycyclohexyl phenylketone, and 2,2-dimethoxy-2-phenyl acetophenone; thioxanthone derivatives such as thioxanthone, diethylthioxanthone, 2-isopropylthioxanthone, and 2-chlorothioxanthone; acylphosphine oxide derivatives such as 2,4,6-trimethylbenzoyldiphenylphosphine oxide, bis(2,4,6-trimethylbenzoyl)phenylphosphine oxide, and bis-(2,6-dimethoxybenzoyl)-2,4,4-trimethylpentylphosphine oxide; oxime ester derivatives such as 1,2-octanedione, 1-[4-(phenylthiol)-,2-(O-benzoyloxime)], ethanone, 1-[9-ethyl-6-(2-methylbenzoyl)-9H-carbazole-3-yl]-, and 1-(O-acetyloxime); and xanthone, fluorenone, benzaldehyde, fluorene, anthraquinone, triphenylamine, carbazole, 1-(4-isopropylphenyl)-2-hydroxy-2-methylpropane-1-one, and 2-hydroxy-2-methyl-1-phenylpropane-1-one.

Examples of commercially available products of the above-described radical generators are as follows, but the products are not limited to these examples.

Irgacure 184, 369, 651, 500, 819, 907, 784, and 2959, CGI-1700, -1750, and -1850, CG24-61, Darocur 1116 and 1173, Lucirin® TPO, LR8893, and LR8970 (manufactured by BASF), and Ubecryl P36 (manufactured by UCB).

Of the above-described radical generators, the component (b) is preferably an acylphosphine oxide-based polymerization initiator. Note that of the above-described radical generators, the acylphosphine oxide-based polymerization initiators are as follows.

Acylphosphine oxide compounds such as 2,4,6-trimethylbenzoyl diphenylphosphine oxide, bis(2,4,6-trimethylbenzoyl)phenylphosphine oxide, and bis(2,6-dimethoxybenzoyl)-2,4,4-trimethylpentylphosphine oxide.

The blending ratio of the component (b) in the curable composition (A) is preferably 0.1 wt % or more and 50 wt % or less with respect to the sum of the component (a), the component (b), and a component (c) (to be described later), that is, the total mass of all the components except for the solvent (d). Also, the blending ratio of the component (b) in the curable composition (A) is more preferably 0.1 wt % or more and 20 wt % or less, and further preferably 1 wt % or more and 20 wt % or less with respect to the total mass of all the components except for the solvent (d). When the blending ratio of the component (b) is set at 0.1 wt % or more, the curing rate of the composition increases, so the reaction efficiency can be improved. Also, when the blending ratio of the component (b) is set at 50 wt % or less, a cured film having mechanical strength to some extent can be obtained.

### <Component (c): Nonpolymerizable Compound>

In addition to the components (a) and (b) described above, the curable composition (A) of the present disclosure can further contain a nonpolymerizable compound as the component (c) within a range that does not impair the effect of the present disclosure. An example of the component (c) is a compound that does not contain a polymerizable functional group such as a (meth)acryloyl group, and does not have the ability to sense light having a predetermined wavelength and generate the polymerization factor (radical) described previously. Examples of the nonpolymerizable compound are a sensitizer, a hydrogen donor, an internal mold release agent, an antioxidant, a polymer component, and other additives. The component (c) can contain a plurality of types of the above-described compounds.

The sensitizer is a compound that is properly added for the purpose of promoting the polymerization reaction and improving the reaction conversion rate. As the sensitizer, it is possible to use one type of a compound alone, or to use two or more types of compounds by mixing them.

An example of the sensitizer is a sensitizing dye. The sensitizing dye is a compound that is excited by absorbing light having a specific wavelength and has an interaction with a photopolymerization initiator as the component (b). The “interaction” herein mentioned is energy transfer or electron transfer from the sensitizing dye in the excited state to the photopolymerization initiator as the component (b). Practical examples of the sensitizing dye are as follows, but the sensitizing dye is not limited to these examples.

An anthracene derivative, an anthraquinone derivative, a pyrene derivative, a perylene derivative, a carbazole derivative, a benzophenone derivative, a thioxanthone derivative, a xanthone derivative, a coumarin derivative, a phenothiazine derivative, a camphorquinone derivative, an acridinic dye, a thiopyrylium salt-based dye, a merocyanine-based dye, a quinoline-based dye, a styryl quinoline-based dye, a ketocoumarin-based dye, a thioxanthene-based dye, a xanthene-based dye, an oxonol-based dye, a cyanine-based dye, a rhodamine-based dye, and a pyrylium salt-based dye.

The hydrogen donor is a compound that reacts with an initiating radical generated from the photopolymerization initiator as the component (b) or a radical at a polymerization growth end, and generates a radical having higher reactivity. The hydrogen donor is preferably added when the photopolymerization initiator as the component (b) is a photo-radical generator.

Practical examples of the hydrogen donor as described above are as follows, but the hydrogen donor is not limited to these examples.

Amine compounds such as n-butylamine, di-n-butylamine, tri-n-butylphosphine, allylthiourea, s-benzylisothiuronium-p-toluenesulfinate, triethylamine, diethylaminoethyl methacrylate, triethylenetetramine, 4,4′-bis(dialkylamino)benzophenone, N,N-dimethylamino ethylester benzoate, N,N-dimethylamino isoamylester benzoate, pentyl-4-dimethylamino benzoate, triethanolamine, and N-phenylglycine; and mercapto compounds such as 2-mercapto-N-phenylbenzoimidazole and mercapto propionate ester.

It is possible to use one type of a hydrogen donor alone, or to use two or more types of hydrogen donors by mixing them. The hydrogen donor can also have a function as a sensitizer.

An internal mold release agent can be added to the curable composition for the purpose of reducing the interface bonding force between a mold and the curable composition, that is, reducing the mold release force in a mold release step (to be described later). In this specification, “internal” means that the mold release agent is added to the curable composition in advance before a curable composition arranging step. As the internal mold release agent, it is possible to use surfactants such as a silicon-based surfactant, a fluorine-based surfactant, and a hydrocarbon-based surfactant. In the present disclosure, however, the addition amount of the fluorine-based surfactant is limited as will be described later. Note that the internal mold release agent according to the present disclosure is not polymerizable. It is possible to use one type of an internal mold release agent alone, or to use two or more types of internal mold release agents by mixing them.

The fluorine-based surfactant includes the following.

A polyalkylene oxide (for example, polyethylene oxide or polypropylene oxide) adduct of alcohol having a perfluoroalkyl group, and a polyalkylene oxide (for example, polyethylene oxide or polypropylene oxide) adduct of perfluoropolyether.

Note that the fluorine-based surfactant can have a hydroxyl group, an alkoxy group, an alkyl group, an amino group, or a thiol group in a portion (for example, a terminal group) of the molecular structure. An example is pentadecaethyleneglycol mono1H,1H,2H,2H-perfluorooctylether.

It is also possible to use a commercially available product as the fluorine-based surfactant. Examples of the commercially available product of the fluorine-based surfactant are as follows.

MEGAFACE® F-444, TF-2066, TF-2067, and TF-2068, and DEO-15 (abbreviation) (manufactured by DIC); Fluorad FC-430 and FC-431 (manufactured by Sumitomo 3M); Surflon® S-382 (manufactured by AGC); EFTOP EF-122A, 122B, 122C, EF-121, EF-126, EF-127, and MF-100 (manufactured by Tochem Products); PF-636, PF-6320, PF-656, and PF-6520 (manufactured by OMNOVA Solutions); UNIDYNE® DS-401, DS-403, and DS-451 (manufactured by DAIKIN); and FUTAGENT® 250, 251, 222F, and 208G (manufactured by NEOS).

The internal mold release agent can also be a hydrocarbon-based surfactant. The hydrocarbon-based surfactant includes an alkyl alcohol polyalkylene oxide adduct obtained by adding alkylene oxide having a carbon number of 2 to 4 to alkyl alcohol having a carbon number of 1 to 50, and polyalkylene oxide.

Examples of the alkyl alcohol polyalkylene oxide adduct are as follows.

A methyl alcohol ethylene oxide adduct, a decyl alcohol ethylene oxide adduct, a lauryl alcohol ethylene oxide adduct, a cetyl alcohol ethylene oxide adduct, a stearyl alcohol ethylene oxide adduct, and a stearyl alcohol ethylene oxide/propylene oxide adduct.

Note that the terminal group of the alkyl alcohol polyalkylene oxide adduct is not limited to a hydroxyl group that can be manufactured by simply adding polyalkylene oxide to alkyl alcohol. This hydroxyl group can also be substituted by a polar functional group such as a carboxyl group, an amino group, a pyridyl group, a thiol group, or a silanol group, or by a hydrophobic group such as an alkyl group or an alkoxy group.

Examples of polyalkylene oxide are as follows.

Polyethylene glycol, polypropylene glycol, their mono or dimethyl ether, mono or dioctyl ether, mono or dinonyl ether, and mono or didecyl ether, monoadipate, monooleate, monostearate, and monosuccinate.

A commercially available product can also be used as the alkyl alcohol polyalkylene oxide adduct. Examples of the commercially available product of the alkyl alcohol polyalkylene oxide adduct are as follows.

Polyoxyethylene methyl ether (a methyl alcohol ethylene oxide adduct) (BLAUNON MP-400, MP-550, and MP-1000) manufactured by AOKI OIL INDUSTRIAL, polyoxyethylene decyl ether (a decyl alcohol ethylene oxide adduct) (FINESURF D-1303, D-1305, D-1307, and D-1310) manufactured by AOKI OIL INDUSTRIAL, polyoxyethylene lauryl ether (a lauryl alcohol ethylene oxide adduct) (BLAUNON EL-1505) manufactured by AOKI OIL INDUSTRIAL, polyoxyethylene cetyl ether (a cetyl alcohol ethylene oxide adduct) (BLAUNON CH-305 and CH-310) manufactured by AOKI OIL INDUSTRIAL, polyoxyethylene stearyl ether (a stearyl alcohol ethylene oxide adduct) (BLAUNON SR-705, SR-707, SR-715, SR-720, SR-730, and SR-750) manufactured by AOKI OIL INDUSTRIAL, randomly polymerized polyoxyethylene polyoxypropylene stearyl ether (BLAUNON SA-50/50 1000R and SA-30/70 2000R) manufactured by AOKI OIL INDUSTRIAL, polyoxyethylene methyl ether (Pluriol® A760E) manufactured by BASF, and polyoxyethylene alkyl ether (EMULGEN series) manufactured by KAO.

A commercially available product can also be used as polyalkylene oxide. An example is an ethylene oxide/propylene oxide copolymer (Pluronic PE6400) manufactured by BASF.

The fluorine-based surfactant shows an excellent mold release force reducing effect and hence is effective as an internal mold release agent. The blending ratio of the component (c) in the curable composition (A) except for the fluorine-based surfactant is preferably 0 wt % or more and 50 wt % or less with respect to the sum of the components (a), (b), and (c), that is, the total mass of all the components except for the solvent (d). The blending ratio of the component (c) in the curable composition (A) except for the fluorine-based surfactant is more preferably 0.1 wt % or more and 50 wt % or less, and further preferably 0.1 wt % or more and 20 wt % or less with respect to the total mass of all the components except for the solvent (d). When the blending ratio of the component (c) except for the fluorine-based surfactant is set at 50 wt % or less, a cured film having mechanical strength to some extent can be obtained.

### <Component (d): Solvent>

The curable composition of the present disclosure contains a solvent having a boiling point of 80° C. or more and less than 250° C. at normal pressure as the component (d). The component (d) is a solvent that dissolves the components (a), (b), and (c). Examples are an alcohol-based solvent, a ketone-based solvent, an ether-based solvent, an ester-based solvent, and a nitrogen-containing solvent. As the component (d), it is possible to use one type of a component alone, or to use two or more types of components by combining them. The boiling point at normal pressure of the component (d) is 80° C. or more, and preferably 140° C. or more. If the boiling point of the component (d) at normal pressure is less than 80° C., volatilization progresses even during the arranging step, and stability of the step is impaired. Also, if the boiling point at normal pressure of the component (d) is 250° C. or more, it is possible that the volatilization of the solvent (d) is insufficient in the subsequent waiting step, so the component (d) remains in the cured film of the curable composition (A).

Examples of the alcohol-based solvent are as follows.

Monoalcohol-based solvents such as methanol, ethanol, n-propanol, iso-propanol, n-butanol, iso-butanol, sec-butanol, tert-butanol, n-pentanol, iso-pentanol, 2-methylbutanol, sec-pentanol, tert-pentanol, 3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethylheptanol-4, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; and polyalcohol-based solvents such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, and glycerin.

Examples of the ketone-based solvent are as follows.

Acetone, methylethylketone, methyl-n-propylketone, methyl-n-butylketone, diethylketone, methyl-iso-butylketone, methyl-n-pentylketone, ethyl-n-butylketone, methyl-n-hexylketone, di-iso-butylketone, trimethylnonanon, cyclohexanone, methylcyclohexanone, 2,4-pentanedione, acetonylacetone, diacetone alcohol, acetophenone, and fenchone.

Examples of the ether-based solvent are as follows.

Ethyl ether, iso-propyl ether, n-butyl ether, n-hexyl ether, 2-ethylhexyl ether, ethylene oxide, 1,2-propylene oxide, dioxolane, 4-methyldioxolane, dioxane, dimethyldioxane, 2-methoxyethanol, 2-ethoxyethanol, ethylene glycol diethyl ether, 2-n-butoxyethanol, 2-n-hexoxyethanol, 2-phenoxyethanol, 2-(2-ethylbutoxy)ethanol, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxy triglycol, tetraethylene glycol di-n-butyl ether, 1-n-butoxy-2-propanol, 1-phenoxy-2-propanol, propylene glycol monomethyl ether, propylene glycol monoethyl ether, propylene glycol monopropyl ether, dipropylene glycol monomethyl ether, dipropylene glycol monoethyl ether, dipropylene glycol monopropyl ether, tripropylene glycol monomethyl ether, tetrahydrofuran, and 2-methyltetrahydrofuran.

Examples of the ester-based solvent are as follows.

Diethyl carbonate, methyl acetate, ethyl acetate, amyl acetate, y-butyrolactone, γ-valerolactone, n-propyl acetate, iso-propyl acetate, n-butyl acetate, iso-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxy triglycol acetate, ethyl propionate, n-butyl propionate, iso-amyl propionate, diethyl oxalate, di-n-butyl oxalate, methyl lactate, ethyl lactate, n-butyl lactate, n-amyl lactate, diethyl malonate, dimethyl phthalate, and diethyl phthalate.

Examples of the nitrogen-containing solvent are as follows.

N-methylformamide, N,N-dimethylformamide, N,N-diethylformamide, acetamide, N-methylacetamide, N,N-dimethylacetamide, N-methylpropionamide, and N-methylpyrrolidone.

Of the above-described solvents, the ether-based solvent and the ester-based solvent are favorable. Note that an ether-based solvent and an ester-based solvent each having a glycol structure are more favorable from the viewpoint of good film formation properties.

Further favorable examples of the solvent are as follows.

Propylene glycol monomethyl ether, propylene glycol monoethyl ether, propylene glycol monopropyl ether, propylene glycol monomethyl ether acetate, propylene glycol monoethyl ether acetate, and propylene glycol monopropyl ether acetate.

A particularly favorable example is propylene glycol monomethyl ether acetate.

In the present disclosure, a favorable solvent is a solvent having at least one of an ester structure, a ketone structure, a hydroxyl group, and an ether structure. More specifically, a favorable solvent is one solvent or a solvent mixture selected from propylene glycol monomethyl ether acetate (boiling point=146° C.), propylene glycol monomethyl ether, cyclohexanone, 2-heptanone, y-butyrolactone, and ethyl lactate.

In the present disclosure, a polymerizable compound having a boiling point of 80° C. or more and less than 250° C. at normal pressure is also usable as the component (d). Examples of the polymerizable compound having a boiling point of 80° C. or more and less than 250° C. at normal pressure are as follows.

Cyclohexyl acrylate (boiling point=198° C.), benzyl acrylate (boiling point=229° C.), isobornyl acrylate (boiling point=245° C.), tetrahydrofurfuryl acrylate (boiling point=202° C.), trimethylcyclohexyl acrylate (boiling point=232° C.), isooctyl acrylate (217° C.), n-octyl acrylate (boiling point=228° C.), ethoxyethoxyethyl acrylate (boiling point=230° C.), divinylbenzene (boiling point=193° C.), 1,3-diisopropenylbenzene (boiling point=218° C.), styrene (boiling point=145° C.), and α-methylstyrene (boiling point=165° C.).

In the arranging step of the present disclosure, when the whole of the curable composition (A) is 100 vol %, the content of the solvent (d) in a case where an inkjet method is used is 0 vol % or more and 95 vol % or less. The content is preferably 70 vol % or more and 95 vol % or less, and further preferably 80 vol % or more and 90 vol % or less. If the content of the solvent (d) is 70 vol % or more, the droplets bond to each other in the waiting step, and a practically continuous liquid film can be obtained. On the other hand, if the content of the solvent (d) is larger than 95 vol %, no thick film can be obtained after the solvent (d) volatilized even when droplets are closely dropped by an inkjet method.

<Temperature when Blending Curable Composition>

When preparing the curable composition (A) of the present disclosure, at least the components (a), (b), and (d) are mixed and dissolved under a predetermined temperature condition. More specifically, the predetermined temperature condition is 0° C. or more and 100° C. or less. Note that the same applies to a case in which the curable composition (A) contains the component (c).

### <Viscosity of Curable Composition>

The curable composition (A) of the present disclosure is a liquid. This is so because droplets of the curable composition (A) are arranged on a substrate by an inkjet method or a spin coating method in an arranging step (to be described later).

In the arranging step of the present disclosure, the viscosity of the curable composition (A) at 23° C. in a case where the inkjet method is used is 2 mPa·s or more and 60 mPa·s or less in a state in which the solvent (d) is contained. The viscosity is preferably 5 mPa·s or more and 30 mPa·s or less, and more preferably 5 mPa·s or more and 15 mPa·s or less. If the viscosity of the curable composition (A) is smaller than 2 mPa·s, the discharge property of droplets by an inkjet method becomes unstable. Also, if the viscosity of the curable composition (A) is larger than 60 mPa·s, it is impossible to form droplets having a volume of about 1.0 to 3.0 pL favorable in this embodiment.

The viscosity in a state in which the solvent (d) volatilized from the curable composition (A), that is, the viscosity of a mixture of components except for the solvent (d) of the curable composition (A) at 23° C. is 1 mPa·s or more and 10,000 mPa·s or less, and preferably 30 mPa·s or more and 1,000 mPa·s or less. Also, the viscosity of a mixture of components except for the solvent (d) of the curable composition (A) at 23° C. is more preferably 30 mPa·s or more and 500 mPa·s or less, and further preferably 120 mPa·s or more and 500 mPa·s or less. When the viscosity of the components except for the solvent (d) of the curable composition (A) is set to 1,000 mPa·s or less, spreading and filling are rapidly completed when bringing the curable composition (A) into contact with a mold. Accordingly, the use of the curable composition (A) of the present disclosure makes it possible to perform an imprint process at high throughput, and suppress pattern defects caused by insufficient filling. Also, when the viscosity of components except for the solvent (d) of the curable composition (A) is set to 1 mPa·s or more, it is possible to prevent an unnecessary flow of droplets of the curable composition (A) after the solvent (d) volatilized. Furthermore, when bringing the curable composition (A) into contact with a mold, the curable composition (A) does not easily flow out from the end portions of the mold.

### <Surface Tension of Curable Composition>

The surface tension of the curable composition (A) of the present disclosure is as follows. The surface tension at 23° C. of the composition containing the components except for the solvent (component (d)) is preferably 5 mN/m or more and 70 mN/m or less. The surface tension at 23° C. of the composition containing the components except for the solvent (component (d)) is more preferably 7 mN/m or more and 50 mN/m or less, and further preferably 10 mN/m or more and 40 mN/m or less. Note that when the surface tension is high, for example, 5 mN/m or more, the capillarity strongly acts, so filling (spreading and filling) is complete within a short time period when the curable composition (A) and a mold are brought into contact with each other. Also, when the surface tension is 70 mN/m or less, a cured film obtained by curing the curable composition has surface smoothness.

### <Contact Angle of Curable Composition>

The contact angle of the curable composition (A) of the present disclosure is as follows. That is, the contact angle of the composition containing the components except for the solvent (component (d)) is preferably 0° or more and 90° or less and particularly preferably 0° or more and 100 or less with respect to both the surface of a substrate and the surface of a mold. If the contact angle is larger than 90°, the capillarity acts in a negative direction (a direction in which the contact interface between the mold and the curable composition is shrunk) inside a pattern of the mold or in a gap between the substrate and the mold, and this may make filling impossible. When the contact angle is small, the capillarity strongly acts, and the filling rate increases.

### <Impurities Mixed in Curable Composition>

The curable composition (A) of the present disclosure preferably contains impurities as little as possible. Note that impurities mean components other than the components (a), (b), (c), and (d) described above. Therefore, the curable composition (A) of the present disclosure is favorably a composition obtained through a refining step. A refining step like this is preferably filtration using a filter.

As this filtration using a filter, it is favorable to mix the components (a), (b), and (c) described above, and filtrate the mixture by using, for example, a filter having a pore diameter of 0.001 μm or more and 5.0 μm or less. When performing filtration using a filter, is it further favorable to perform the filtration in multiple stages, or to repetitively perform the filtration a plurality of times (cycle filtration). It is also possible to re-filtrate a liquid once filtrated through a filter, or perform filtration by using filters having different pore diameters. Examples of the filter for use in filtration are filters made of, for example, a polyethylene resin, a polypropylene resin, a fluorine resin, and a nylon resin, but the filter is not particularly limited. Impurities such as particles mixed in the curable composition can be removed through the refining step as described above. Consequently, it is possible to prevent impurities mixed in the curable composition from causing pattern defects by forming unexpected unevenness on a cured film obtained after the curable composition is cured.

Note that when using the curable composition of the present disclosure in order to fabricate a semiconductor integrated circuit, it is favorable to avoid mixing of impurities (metal impurities) containing metal atoms in the curable composition as much as possible so as not to obstruct the operation of a product. The concentration of the metal impurities contained in the curable composition is preferably 10 ppm or less, and more preferably 100 ppb or less.

### [Substrate]

In this specification, a member on which the curable composition (A) is arranged is explained as a substrate.

This substrate is a processing target substrate, and a silicon wafer is normally used. The substrate can have a processing target layer on the surface. On the substrate, another layer can also be formed below the processing target layer. When a quartz substrate is used as the substrate, a replica (replica mold) of a mold for imprint can be manufactured. However, the substrate is not limited to a silicon wafer or a quartz substrate. The substrate can freely be selected from those known as semiconductor device substrates such as aluminum, a titanium-tungsten alloy, an aluminum-silicon alloy, an aluminum-copper-silicon alloy, silicon oxide, and silicon nitride. Note that the processing target layer on the uppermost surface of the substrate is preferably treated by a surface treatment such as a silane coupling treatment, a silazane treatment, or deposition of an organic thin film, thereby improving the adhesion to the curable composition (A). As a practical example of the organic thin film to be deposited as the surface treatment, an adhesion layer described in Japanese Patent Laid-Open No. 2009-503139 can be used.

### [Adhesion Layer Forming Method]

Formation of an adhesion layer (adhesion primer layer) can be achieved by an arbitrary vapor phase coating method known in the technical field. In some embodiments, the adhesion primer layer composition can be vaporized by heating during a vapor phase coating step. In other embodiments, the adhesion primer layer composition can be vaporized by a combination of heating and pressure reduction during the vapor phase coating step. In still other embodiments, the adhesion primer layer composition can be vaporized by bubbling the composition by a carrier gas, for example, nitrogen or argon. The boiling point of the adhesion primer layer composition under an ambient pressure can be, for example, less than about 350° C. In some embodiments, the boiling point of the adhesion primer layer composition can be less than about 250° C. The vapor phase coating temperature can be less than the boiling point of the adhesion primer layer composition under a reduced pressure atmosphere or by a gas bubbling method.

In some embodiments, the adhesion primer layer can be adhered to one surface of the substrate by vapor phase coating. In other embodiments, the adhesion primer layer can simultaneously be adhered to two or more surfaces of the substrate by vapor phase coating. The substrate can be arranged on a pin lift to, for example, allow vapor to substantially simultaneously contact two or more surfaces of the substrate without rotating or rearranging the substrate between the coating of the first surface and the second surface of the substrate. Vapor phase coating of the adhesion primer layer thus enables batch processing of substrates, and this can decrease the processing time required for the spin coating step that is conventionally used to adhere the adhesion primer layer.

### Pattern Forming Method

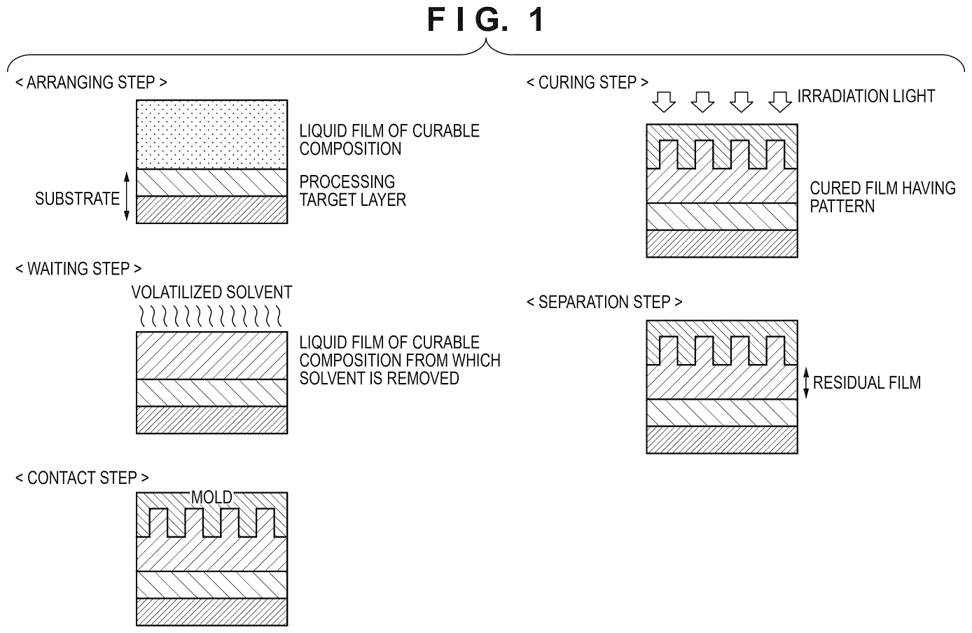

The pattern forming method according to this embodiment will be explained with reference to FIG. 1. The cured film formed by this embodiment is preferably a film having a pattern with a size of 1 nm or more and 10 mm or less, and more preferably a film having a pattern with a size of 10 nm or more and 100 μm or less. The film forming method according to this embodiment forms a film of a curable composition in a space between a mold and a substrate by using a photoimprint method. However, the curable composition can also be cured by another energy (for example, heat or an electromagnetic wave).

The film forming method according to this embodiment will be explained below. The pattern forming method according to this embodiment includes, for example, an arranging step, a waiting step, a contact step, a curing step, and a separation step. The arranging step is a step of arranging a liquid film of the curable composition (A) on a substrate. The waiting step is a step of waiting until the component (d) solvent of the curable composition (A) volatilizes. The contact step is a step of bringing the curable composition (A) and a mold in contact with each other. The curing step is a step of curing the curable composition (A). The separation step is a step of separating the mold from the cured film of the curable composition (A). The waiting step is performed after the arranging step, the contact step is performed after the waiting step, the curing step is performed after the contact step, and the separation step is performed after the curing step.

The pattern forming method according to this embodiment further includes an inversion layer forming step, an excess inversion layer removing step, and a residual film etching step. The inversion layer forming step is a step of forming an inversion layer on the cured film of the curable composition (A). The excess inversion layer removing step is a step of removing the inversion layer formed on the upper portion of the convex portion of the cured film of the curable composition (A). The residual film etching step is a step of removing the residual film of the cured film of the curable composition (A) using the inversion layer remaining in the concave portion of the cured film of the curable composition (A) as a mask. The excess inversion layer removing step is performed after the inversion layer forming step, and the residual film etching step is performed after the excess inversion layer removing step.

### <Arranging Step>

In the arranging step, as schematically shown in FIG. 1, a liquid film of the curable composition (A) is arranged on a substrate. A processing target layer is formed on the uppermost layer of the substrate.

As an arranging method of arranging the liquid film of the curable composition (A) on the substrate, an inkjet method or a spin coating method is preferably used.

In a case where the inkjet method is used, it is favorable to arrange the droplets of the curable composition (A) densely on a region of the substrate, which faces a region in which concave portions forming a pattern on a mold densely exist. In addition, it is favorable to arrange the droplets of the curable composition (A) sparsely on a region of the substrate, which faces a region in which concave portions forming a pattern on a mold sparsely exist. Consequently, a film (residual film) of the curable composition (A) formed on the substrate is controlled to have a uniform thickness regardless of the sparsity and density of the pattern of the mold. When discretely arranging the droplet of the curable composition (A) using the inkjet method, it is preferable that all the droplets bond to each other to form a practically continuous liquid film in the waiting step to be described later. In this case, since a spread process is omitted in the subsequent contact step, the time needed for the contact step is short.

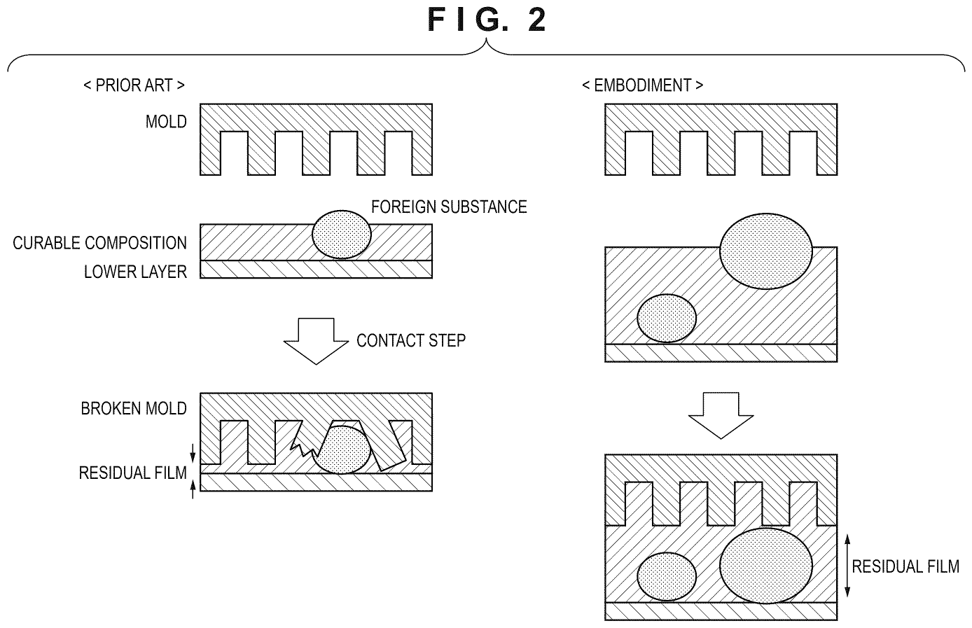

In the present disclosure, the amount of the curable composition (A) arranged on the substrate is adjusted such that the thickness of the residual film sandwiched between the most projecting portion of the mold and the substrate is 1 time or more and 20 times or less the depth of the mold pattern. The amount is preferably 1 time or more and 6 times or less, further preferably 1 time or more and 4 times or less, and particularly preferably 2 times or more and 4 times or less. For example, if the depth of the mold pattern is 50 nm, the thickness of the residual film is 50 nm or more and 1,000 nm or less, preferably 50 nm or more and 300 nm or less, further preferably 50 nm or more and 200 nm or less, and particularly preferably 100 nm or more and 200 nm or less. The thicker the residual film thickness is, the lower the possibility of breakage of the mold pattern by a foreign substance that can exist between the mold and the substrate is. FIG. 2 shows a behavior that the concave-convex pattern of the mold is broken by a foreign substance sandwiched between the mold and the substrate, as compared to the prior art. In the imprint technique, if a foreign substance larger than the residual film thickness is sandwiched, the concave-convex pattern of the mold is broken. In the present disclosure, the residual film is thicker than in the conventional technique. Hence, even if a foreign substance larger than before exists, the foreign substance is buried in the residual film, preventing breakage. However, if the residual film is too thick, it is difficult to expose the substrate surface in the residual film etching step to be described later.

Also, in the present disclosure, since the residual film is thick, the allowance to the concave-convex pattern height difference on the substrate surface is high. For example, if the residual film thickness is 20 nm in the conventional technique, the substrate is preferably planarized such that the concave-convex pattern height difference is less than 20 nm. On the other hand, if the residual film thickness is 200 nm in the present disclosure, the substrate is allowed to have a concave-convex pattern height difference less than 200 nm.

### <Waiting Step>

In the present disclosure, a waiting step of volatilizing the component (d) that is the solvent is provided after the arranging step and before the contact step. If the curable composition (A) does not contain the component (d), the waiting step can be omitted. If the total weight of the components other than the component (d) is 100 vol %, the remaining amount of the component (d) in a liquid film F after the waiting step is preferably 10 vol % or less. If the remaining amount of the component (d) is larger than 10 vol %, the mechanical property of the cured film may be low.

The waiting step is 0.1 sec to 600 sec, and preferably 10 sec to 300 sec. If the inkjet method is used in the arranging step, it is preferable to wait until the discretely arranged droplets of the curable composition (A) bond to each other. If the waiting step is shorter than 0.1 sec, volatilization of the component (d) may be insufficient. If the waiting step exceeds 600 sec, productivity is low.

In the waiting step, it is possible to perform a baking step of heating the substrate and the curable composition (A), or ventilate the atmospheric gas around the substrate, for the purpose of accelerating the volatilization of the solvent (d). The baking step is performed at, for example, 30° C. or more and 200° C. or less, preferably 80° C. or more and 150° C. or less, and particularly preferably 80° C. or more and 110° C. or less. The heating time can be 10 sec or more and 600 sec or less. The baking step can be performed by using a known heater such as a hotplate or an oven.

If the solvent (d) is volatilized in the waiting step, a liquid film formed by the components (a), (b), and (c) remains on the substrate. The average film thickness of the liquid film from which the solvent (d) is volatilized (removed) is smaller than that of the liquid film immediately after the arranging step by an amount of volatilization of the solvent (d).

### <Contact Step>

In the contact step, as schematically shown in FIG. 1, the liquid film of the curable composition (A) from which the solvent (d) is removed is brought into contact with the mold. The contact step includes a step of a changing a state in which the curable composition (A) and the mold are not in contact with each other to a state in which they are in contact with each other, and a step of maintaining the state in which they are in contact with each other. As a consequence, the liquid of the curable composition (A) is filled in the concave portions of fine patterns on the surface of the mold, and the liquid forms a liquid film filled in the fine patterns of the mold.

The contact step is preferably 0.1 sec or more and 3 sec or less, and particularly preferably 0.1 sec or more and 1 sec or less. If the contact step is shorter than 0.1 sec, spreading and filling become insufficient, so many defects called incomplete filling defects tend to occur. If the contact step is longer than 3 sec, productivity is low.

When the curing step includes a photoirradiation step, a mold made of a light-transmitting material is used as the mold by taking this into consideration. Favorable practical examples of the type of the material forming the mold are glass, quartz, PMMA, a photo-transparent resin such as a polycarbonate resin, a transparent metal deposition film, a soft film such as polydimethylsiloxane, a photo-cured film, and a metal film. Note that when using the photo-transparent resin as the material forming the mold, a resin that does not dissolve in components contained in a curable composition is selected. Quartz is particularly preferable as the material forming the mold because the thermal expansion coefficient is small and pattern distortion is small.

A pattern formed on the surface of the mold has a height of, for example, 4 nm or more and 200 nm or less. As the pattern height of the mold decreases, it becomes possible to decrease the force of releasing the mold from the cured film of the curable composition, that is, the mold release force in the separation step, and this makes it possible to decrease the number of mold release defects remaining in the mold because the pattern of the curable composition is torn off. Also, in some cases, the pattern of the curable composition elastically deforms due to the impact when the mold is released, and adjacent pattern elements come in contact with each other and adhere to each other or break each other. Note that to avoid these inconveniences, it is advantageous to make the height of pattern elements be about twice or less the width of the pattern elements (make the aspect ratio be 2 or less). On the other hand, if the height of pattern elements is too small, the processing accuracy of the processing target layer on the substrate decreases.

A surface treatment can also be performed on the mold before performing the contact step, in order to improve the detachability of the mold with respect to the curable composition (A). An example of this surface treatment is to form a mold release agent layer by coating the surface of the mold with a mold release agent. Examples of the mold release agent to be applied on the surface of the mold are a silicon-based mold release agent, a fluorine-based mold release agent, a hydrocarbon-based mold release agent, a polyethylene-based mold release agent, a polypropylene-based mold release agent, a paraffine-based mold release agent, a montane-based mold release agent, and a carnauba-based mold release agent. It is also possible to suitably use a commercially available coating-type mold release agent such as Optool® DSX manufactured by Daikin. Note that it is possible to use one type of a mold release agent alone, or use two or more types of mold release agents together. Of the mold release agents described above, fluorine-based and hydrocarbon-based mold release agents are particularly favorable.

In the contact step, the pressure to be applied to the curable composition (A) when bringing the mold into contact with the curable composition (A) is not particularly limited, and is, for example, 0 MPa or more and 100 MPa or less. Note that when bringing the mold 106 into contact with the curable composition (A), the pressure to be applied to the curable composition (A) is preferably 0 MPa or more and 50 MPa or less, more preferably 0 MPa or more and 30 MPa or less, and further preferably 0 MPa or more and 20 MPa or less.

The contact step can be performed in any of a normal air atmosphere, a reduced-pressure atmosphere, and an inert-gas atmosphere. However, the reduced-pressure atmosphere or the inert-gas atmosphere is favorable because it is possible to prevent the influence of oxygen or water on the curing reaction. Practical examples of an inert gas to be used when performing the contact step in the inert-gas atmosphere are nitrogen, carbon dioxide, helium, argon, various freon gases, and gas mixtures thereof. When performing the contact step in a specific gas atmosphere including a normal air atmosphere, a favorable pressure is 0.0001 atm or more and 10 atm or less.

### <Curing Step>

In the curing step as schematically shown in FIG. 1, the curable composition (A) is cured by being irradiated with irradiation light as curing energy, thereby forming a cured film. In the curing step, for example, the curable composition (A) is irradiated with the irradiation light through the mold. More specifically, the curable composition (A) filled in the fine pattern of the mold is irradiated with the irradiation light through the mold. Consequently, the curable composition (A) filled in the fine pattern of the mold is cured and forms the cured film having the pattern.

The irradiation light is selected in accordance with the sensitivity wavelength of the curable composition (A). More specifically, the irradiation light is properly selected from ultraviolet light, X-ray, and an electron beam each having a wavelength of 150 nm or more and 400 nm or less. Note that the irradiation light is particularly preferably ultraviolet light. This is so because many compounds commercially available as curing assistants have sensitivity to ultraviolet light. Examples of a light source that emits ultraviolet light are a high-pressure mercury lamp, an ultrahigh-pressure mercury lamp, a low-pressure mercury lamp, a Deep-UV lamp, a carbon arc lamp, a metal halide lamp, a xenon lamp, a KrF excimer laser, an ArF excimer laser, and an F₂ laser. Note that the ultrahigh-pressure mercury lamp is particularly favorable as the light source for emitting ultraviolet light. It is possible to use one light source or a plurality of light sources. Light can be emitted to the entire region of the curable composition (A) filled in the fine pattern of the mold, or to only a partial region thereof (by limiting the region). It is also possible to intermittently emit light to the entire region of the substrate a plurality of times, or to continuously emit light to the entire region of the substrate. Furthermore, a first region of the substrate can be irradiated with light in a second irradiation process, and a second region different from the first region of the substrate can be irradiated with light in the second irradiation process.

### <Separation Step>

In the separation step as schematically shown in FIG. 1, the mold is released from the cured film. When the mold is released from the cured film having the pattern, the cured film having a pattern formed by inverting the fine pattern of the mold is obtained in an independent state. In this state, a cured film remains in concave portions of the cured film having the pattern. This film is called the residual film.

A method of releasing the mold from the cured film having the pattern can be any method provided that the method does not physically break a part of the cured film having the pattern during the release, and various conditions and the like are not particularly limited. For example, it is possible to fix the substrate and move the mold away from the substrate. It is also possible to fix the mold and move the substrate away from the mold. Furthermore, the mold can be released from the cured film having the pattern by moving both the mold and the substrate in exactly opposite directions.

### <Repetition>

A series of steps (a fabrication process) having the above-described steps from the arranging step to the separation step in this order make it possible to obtain a cured film having a desired concave-convex pattern shape (a pattern shape conforming to the concave-convex shape of the mold) in a desired position.

In the pattern forming method of the present disclosure, a repetition unit (shot) from the arranging step to the separation step can repetitively be performed a plurality of times on the same substrate. Thus, the cured film having a plurality of desired patterns in desired positions of the substrate can be obtained. In an example, in the same space where the cleanness is 0.01 μm or more and the total amount of particles is 10 pieces/m³ or less, the steps from the adhesion layer forming step to the separation step are continuously executed.

In the present disclosure, an inversion process to be described later in detail is executed to process the processing target layer on the substrate using the cured film having the pattern shape, which is obtained by the arranging step to the separation step.

### <Inversion Layer Forming Step>

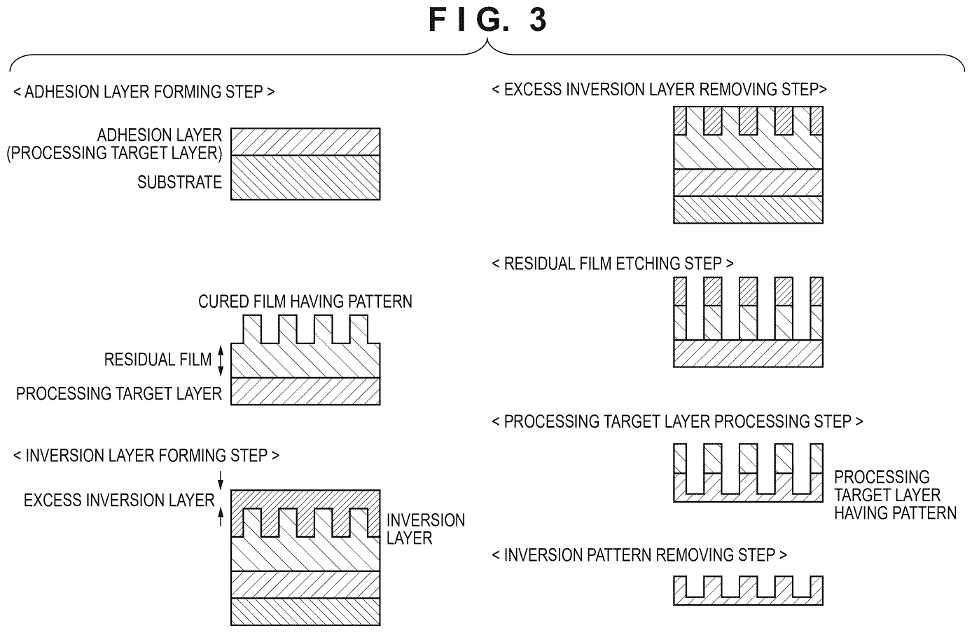

As shown in FIG. 3, an inversion layer is formed on the cured film having the pattern shape formed by the arranging step to the separation step to bury the concave portions of the pattern.

The material of the inversion layer can be selected from silicon-based materials such as SiO₂ and SiN, organic materials containing silicon, metal oxide film materials such as TiO₂ and Al₂O₃, and general metal materials.

For example, as a method of forming an inversion layer using SiO₂, spin coating of a Spin-On-Glass (SOG) material, or plasma CVD deposition by TEOS (Tetra Ethyl Ortho Silicate) can be used. Examples of commercially available SOG are T-111 manufactured by Honeywell and OCD T-12 manufactured by TOKYO OHKA KOGYO, but the material is not limited to these.

### <Excess Inversion Layer Removing Step>

In the inversion layer forming step, an inversion layer is formed even on the upper portions of the convex portions of the cured film having the pattern shape (such a part of the inversion layer will be referred to as an “excess inversion layer” hereinafter). An excess inversion layer needs to be removed until the upper portions of the convex portions of the cured film having the pattern shape are exposed, as shown in FIG. 3. In the removing step, in a state in which the inversion layer is buried in the concave portions of the concave-convex pattern, the upper layer portion of the excess inversion layer is removed to expose the top surfaces of the convex portions of the concave-convex pattern.

A detailed method for removing the excess inversion layer is not particularly limited, and a conventionally known method, for example, dry etching can be used. A conventionally known dry etching apparatus can be used for dry etching. A source gas in dry etching is appropriately selected in accordance with the element composition of the inversion layer, and it is possible to use fluorocarbon gases such as CF₄, CHF₄, C₂F₆, C₃F₈, C₄F₈, C₅F₈, C₄F₆, CCl₂F₂, and CBrF₃ or halogen gases such as CCl₄, BCl₃, PCl₃, SF₆, and Cl₂. Note that these gases can also be used as a mixture.

### <Residual Film Etching Step>

Using, as a processing mask, the inversion layer remaining while being buried in the pattern concave portions, the cured film having the pattern shape is etched starting from the portion exposed by the excess inversion layer removing step. The etching is continued until the processing target layer surface of the substrate is exposed. With this step, a pattern (to be referred to as an inversion pattern hereinafter) in which the concave-convex pattern is inverted from that of the cured film of the curable composition (A) is formed, as shown in FIG. 1. A detailed method of etching is not particularly limited and a known method, for example, dry etching can be used. A known dry etching apparatus can be used for dry etching. A source gas in dry etching can appropriately be selected in accordance with the element composition of a resist layer, and it is possible to use gases containing oxygen atoms such as O₂, CO, and CO₂, inert gases such as He, N₂, and Ar, or gases such as N₂, H₂, and NH₃. Note that these gases can also be used as a mixture.

### <Processing Target Layer Processing Step>

Furthermore, in the present disclosure, as shown in FIG. 3, using the inversion pattern as a mask, the processing target layer on the substrate is etched, thereby obtaining a processing target layer having the pattern shape. Using the inversion pattern as a processing mask, ion implantation may be performed for the processing target layer. Etching of the processing target layer may be executed under the same conditions as the etching of the excess inversion layer described above, or may be executed under different conditions suitable for etching of the processing target layer. After processing of the processing target layer, the inversion pattern serving as the processing mask may be removed.

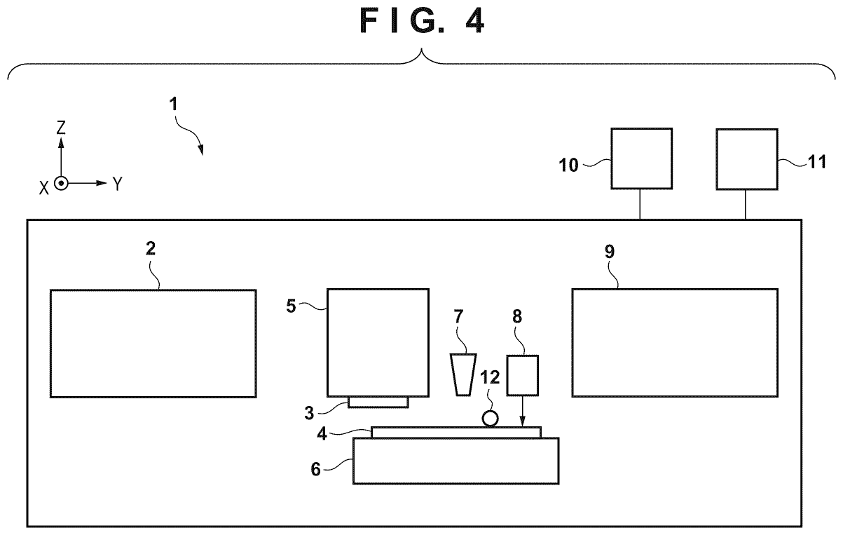

FIG. 4 shows an example of the configuration of an imprint apparatus 1 according to the embodiment to which the above-described pattern forming method is applied. In FIG. 4, the configuration of the imprint apparatus will be explained in accordance with an XYZ coordinate system in which a plane parallel to the surface of the substrate is defined as the XY plane. Typically, the XY plane is a horizontal plane, and the Z-axis is along the vertical direction.

The imprint apparatus 1 includes an adhesion layer forming unit 2, an imprint head 5, a substrate stage 6, a nozzle 7, a substrate inspection unit 8, a substrate storage unit 9, a storage unit 10, and a control unit 11. The substrate stage 6 is a stage that holds a substrate 4 with an adhesion layer formed by the adhesion layer forming unit 2, and moves it in the horizontal direction. The nozzle 7 discharges an imprint material onto the substrate 4. The imprint head 5 holds a mold 3 and performs posture control of the mold 3 and vertical driving for bringing the concave-convex pattern of the mold 3 into contact with the imprint material. The substrate inspection unit 8 detects a foreign substance 12 on the substrate 4 and stores the position information of the detected foreign substance 12 in the storage unit 10. The substrate storage unit 9 can store the substrate 4 inside.

The substrate 4 is loaded into the imprint apparatus 1 by a substrate conveyance mechanism (not shown) and placed on the substrate stage 6. The substrate conveyance mechanism can also convey the substrate 4 to the substrate storage unit 9, and the processed substrate 4 is unloaded from the imprint apparatus 1. The mold 3 is conveyed by a mold conveyance mechanism (not shown) and held by the imprint head 5.

### [Article Manufacturing Method]

The inversion pattern formed by the pattern forming method according to the present disclosure can directly be used as the constituent member of at least some of various kinds of articles. Also, the inversion pattern is temporarily used as a processing mask in etching or ion implantation for the processing target layer on the substrate. In the processing step of the processing target layer on the substrate, after etching or ion implantation is performed for the processing target layer, the inversion pattern serving as the processing mask is removed. Various kinds of articles can thus be manufactured.

An article is, for example, an electric circuit element, an optical element, MEMS, a recording element, a sensor, or a mold.

Examples of the electric circuit element are volatile or nonvolatile semiconductor memories such as a DRAM, an SRAM, a flash memory, and an MRAM, and semiconductor elements such as an LSI, a CCD, an image sensor, and an FPGA. If the processing target layer is an insulating layer, it can be used as an interlayer dielectric film included in the above-described semiconductor memory or semiconductor element.

The processing target layer having the pattern shape obtained by the arranging step to the processing target layer etching step can be used as an optical member (or as one member of an optical member) such as a diffraction grating or a polarizing plate. In a case like this, an optical element including at least a substrate, and a processing target layer having a pattern shape on the substrate can be obtained. Examples of the optical element are a micro lens, a light guide body, a waveguide, an antireflection film, a diffraction grating, a polarizer, a color filter, a light-emitting element, a display, and a solar battery.

Examples of the MEMS are a DMD, a microchannel, and an electromechanical transducer. Examples of the recording element are optical disks such as a CD and a DVD, a magnetic disk, a magneto-optical disk, and a magnetic head. Examples of the sensor are a magnetic sensor, a photosensor, and a gyro sensor. An example of the mold is a mold for imprint.

### EXAMPLES

More practical examples will be explained in order to supplement the above-described embodiments.

The contents of the present disclosure will be described below in more detail using the examples, but the technical scope of the present disclosure is not limited to the examples to be described below.

### <Estimate of Possibility of Breakage of Mold Pattern>

The number of particles remaining in a curable composition (A) in a liquid form filtrated using a polyethylene resin filter and a nylon resin filter was measured using a liquid-borne particle counter KS-19F available from Rion Co., LTD. The number of particles having a diameter of 70 nm or more was 117 pieces/ml, and the number of particles having a diameter of 200 nm or more was 3 pieces/ml. The larger the diameter of the particle was, the smaller the number of particles was. According to the measurement result, it can be said that the probability that the mold is broken by sandwiching particles remaining in the curable composition (A) in a case where the residual film thickness is 200 nm is 1/39 or less as compared to a case where the residual film thickness is 70 nm, and the probability of breakage of the mold lowers as the residual film thickness increases.

### <Dry Etching Resistance: Inkjet Method>

Curable compositions (AC1), (AC2), and (A1) to (A3) shown in Table 1 are adjusted in accordance with the following procedure. Components (a) to (c) shown in Table 1 are mixed. Next, a component (d) is added such that the content of the component (d) is 80 vol % with respect to the content (20 vol %) of the mixture of the components (a) to (c), thereby obtaining the curable composition (A) having a total content of 100 vol %.

Abbreviations in tables are as follows.
a1: 2-phenylphenoxyethyl acrylate
a2: tricyclodecanedimethanol diacrylate
a3: 3-phenoxybenzyl acrylate
a4: BPh43DA
a5: Na13MDA
b1: bis(2,4,6-trimethylbenzoyl)phenylphosphine oxide
d1: cyclohexanone
d2: benzyl acrylate

TABLE 1

| | Comparative | Comparative | | | |
|---|---|---|---|---|---|
| | Example 1 | Example 2 | Example | Example | Example |
| | (AC1) | (AC2) | 1 (A1) | 2 (A2) | 3 (A3) |
| Component (a)/ | a1/0 | a1/30 | a1/40 | a1/70 | a1/100 |
| parts by weight | a2/100 | a2/70 | a2/60 | a2/30 | a2/0 |
| Component (b)/ | b1/ | ← | ← | ← | ← |
| parts by weight | 5 | | | | |
| Component (c)/ | none | ← | ← | ← | ← |
| parts by weight | | | | | |
| Total vol % of | 20 | ← | ← | ← | ← |
| components (a) | | | | | |
| to (c) | | | | | |
| Component (d)/ | d1/ | ← | ← | ← | ← |
| vol % | 80 | | | | |
| OP | 3.29 | 3.05 | 2.98 | 2.77 | 2.57 |
| Processing | x | x | ○ | ○ | ○ |
| resistance | | | | | |

Spin on glass (SOG, T-111 manufactured by Honeywell) is deposited as a processing target layer having a thickness of 300 nm on a silicon substrate, and an adhesion layer described in Japanese Patent Laid-Open No. 2009-503139 is deposited as an adhesion layer having a thickness of 5 nm on the surface of the T-111 layer. For the curable compositions (AC1), (AC2), and (A1) to (A3) shown in Table 1, the arranging step to the separation step were executed. The pattern height of the mold, that is, the thickness of the inversion layer is set to 50 nm, and the residual film thickness is set to 200 nm. The inkjet method is used in the arranging step, and in the waiting step, the structure is left to stand for 10 min at room temperature.

Next, the inversion layer forming step to the processing target layer processing step are executed for the cured films of the curable compositions (AC1), (AC2), and (A1) to (A3). As the inversion layer, T-111 manufactured by Honeywell is used, like the processing target layer. In the excess inversion layer removing step and the residual film etching step, a high-density plasma etching apparatus NE-550 manufactured by ULVAC is used. These steps are executed using CF₄/CHF₃ mixed gas plasma and O₂/Ar mixed gas plasma, respectively.

A case where the T-111 layer that is the processing target layer can be processed until the silicon substrate surface is exposed in the processing target layer processing step is indicated by ∘, and a case where a failure such as disappearance of the cured film before the substrate surface is exposed occurs is indicated by x in Table 1.

The result shows that, in the inversion process of the present disclosure using a curable composition having an OP of 3.00 or less, the same processing performance as a conventional inversion process using a spin-on-carbon (SOC) layer can be obtained.

### <Volatility: Inkjet Method>

Curable compositions (AC3), and (A4) to (A7) shown in Table 2 are adjusted in accordance with the following procedure. Components (a) to (c) shown in Table 2 are mixed. Next, a component (d) is added such that the content of the component (d) is 80 vol % with respect to the content (20 vol %) of the mixture of the components (a) to (c), thereby obtaining the curable composition (A) having a total content of 100 vol %.

TABLE 2

| | Comparative | | | | |
|---|---|---|---|---|---|
| | Example 3 | Example | Example | Example | Example |
| | (AC3) | 4 (A4) | 5 (A5) | 6 (A6) | 7 (A7) |
| Component | a2/100 | a1/100 | a3/100 | a4/100 | a5/100 |
| (a)/parts by weight | | | | | |
| Component | b1/5 | ← | ← | ← | ← |
| (b)/parts by weight | | | | | |
| Component | none | ← | ← | ← | ← |
| (c)/parts by weight | | | | | |
| Total vol % of | 20 | ← | ← | ← | ← |
| components (a) to | | | | | |
| (c) | | | | | |
| Component | d2/80 | ← | ← | ← | ← |
| (d)/vol % | | | | | |
| 80° C. vapor | 0.0024 | 0.0006 | 0.0004 | <0.0001 | <0.0001 |
| pressure of (a) | | | | | |
| Film decrease | x | ○ | ○ | ○ | ○ |

Spin on glass (SOG, T-111 manufactured by Honeywell) is deposited as a processing target layer having a thickness of 300 nm on a silicon substrate, and an adhesion layer described in Japanese Patent Laid-Open No. 2009-503139 is deposited as an adhesion layer having a thickness of 5 nm on the surface of the T-111 layer. For the curable compositions (AC3), and (A4) to (A7) shown in Table 2, the arranging step to the waiting step are executed. In the waiting step, the baking step is executed on a hot plate at 80° C. for 60 sec. The film thickness of the curable composition is measured before and after the baking step. A film decrease of 10 nm or more is indicated by x, and a film decrease less than 10 nm is indicated by ∘ in Table 2.

The result demonstrates that the polymerizable compound (a) whose vapor pressure at 80° C. is 0.001 mmHg or less can prevent volatilization at the time of baking step.

### <Mold Breakage Evaluation>

### Example 8

One mL of acrylic oxymethyltrimethoxysilane stock liquid was placed in a metal dish. A silicon wafer was placed facing the liquid surface, and the silicon wafer surface was exposed to vapor for 15 to 60 sec. The substrate was exposed to ambient conditions for less than 10 min and acrylic oxymethyltrimethoxysilane was applied to the silicon wafer surface by vapor phase coating.

After that, the arranging step to the waiting step were executed for the curable composition (A1). The inkjet method was used in the arranging step. In the waiting step, the baking step was executed on a hot plate at 80° C. for 60 sec. After that, the contact step to the separation step were executed, and the arranging step to the separation step were repeated.

Vapor phase coating to the separation step were executed in the same space. In the space, the cleanness was 0.01 μm or more, and the total amount of particles is 96 pieces/m³.

### Example 9

Under the same conditions as in Example 8 except that the cleanness was 0.01 μm or more, and the total amount of particles was 8 pieces/m³, vapor phase coating to the separation step were executed, and the arranging step to the separation step were repeated.

### Comparative Example 10

Under the same conditions as in Example 8 except that acrylic oxymethyltrimethoxysilane was applied by the spin coating method, the process was executed up to the separation step, and the arranging step to the separation step were repeated.

### Comparative Example 11

Vapor phase coating to the separation step were executed under the same conditions as in Example 9 except that the silicon wafer was exposed to an environment in which the cleanness was 0.01 μm or more, and the total amount of particles is 120 pieces/m³ for less than 1 sec immediately after vapor phase coating.

### <Mold Breakage Evaluation Method>

For mold breakage evaluation, a commercially available flat type nanoimprint mold (material: quartz, pattern: 12-nm line & space, shape: 4-inch wafer, pattern height: 40 nm) manufactured by HOYA was used.

Every time pattern formation was repeated 100 times, the number of cracks in the mold was counted using an optical microscope, and evaluation was performed based on the following evaluation criteria. The result is shown in Table 3.

### (Evaluation Criteria)

AA: Even if pattern formation was repeated 1,000 times, the number of cracks was less than 3.

A: Even if pattern formation was repeated 500 times, the number of cracks was less than 3.

B: If pattern formation was repeated 100 times, the number of cracks was 10 or more.

TABLE 3

| | | | Comparative | Comparative |
|---|---|---|---|---|
| | Example 8 | Example 9 | Example 10 | Example 11 |
| Mold | A | AA | B | B |
| breakage | | | | |

As shown in Table 3, when all steps from the vapor phase coating step to the separation step were executed in the environment of high cleanness, it was demonstrated that breakage of the mold was remarkably decreased.

According to the above-described various embodiments, it is possible to provide a new technique concerning a pattern forming method and an article manufacturing method.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-024486, filed Feb. 18, 2025 which is hereby incorporated by reference herein in its entirety.

What is claimed is:

1. A pattern forming method comprising:
forming an adhesion layer on a substrate using a vapor phase coating method;
after the forming the adhesion layer, arranging a curable composition (A) containing a polymerizable compound (a) on the adhesion layer formed on the substrate;
after the arranging, bringing the curable composition (A) on the substrate into contact with a mold with a concave-convex pattern, in which a thickness of a residual film sandwiched between a most projecting portion of the mold and the substrate is not less than 50 nm and a height difference of the concave-convex pattern of the mold is not more than the thickness of the residual film;
after the bringing the curable composition into contact with the mold, curing the curable composition (A) to form a cured film;
after the curing, separating the curable composition (A) and the mold from each other;
after the separating, forming an inversion layer on the concave-convex pattern transferred from the mold onto the cured film;
after the forming the inversion layer, removing an upper layer portion of the inversion layer such that a top surface of a convex portion of the concave-convex pattern is exposed in a state in which the inversion layer is buried in a concave portion of the concave-convex pattern; and
after the removing, etching the cured film up to a surface of the substrate to form an inversion pattern using the inversion layer buried in the concave portion as a mask,
wherein in the same space where cleanness is not less than 0.01 μm and a total amount of particles is not more than 10 pieces/m³, steps from the forming the adhesion layer to the separating are continuously executed.

2. The method according to claim 1, wherein in the forming the adhesion layer, an adhesion primer layer adhered to the substrate by covalent bond is formed as the adhesion layer using the vapor phase coating method.

3. The method according to claim 2, wherein the adhesion primer layer is a layer containing a polyfunctional component to be covalently bonded to the curable composition (A).

4. The method according to claim 1, wherein in the arranging, a plurality of droplets of the curable composition (A) are discretely arranged using an inkjet method.

5. The method according to claim 1, wherein
the curable composition (A) contains a solvent (d),
the polymerizable compound (a) contains a compound having one of an aromatic structure, an aromatic heterocyclic structure, and an alicyclic structure,
the curable composition (A) has a viscosity of not less than 2 mPa·s and not more than 60 mPa·s at 23° C.,
the curable composition (A) has a viscosity of not less than 1 mPa·s and not more than 10,000 mPa·s in a state in which the solvent (d) is removed, and
a content of the solvent (d) with respect to whole of the curable composition is not less than 0 vol % and not more than 95 vol %.

6. The method according to claim 1, wherein the Ohnishi Parameter (OP) of the polymerizable compound (a) is not less than 2.00 and not more than 3.00.

7. The method according to claim 1, wherein a vapor pressure of the polymerizable compound (a) at 80° C. is not more than 0.001 mmHg.

8. The method according to claim 3, wherein a boiling point of the polyfunctional component is not more than 350° C.

9. The method according to claim 3, wherein a viscosity of the polyfunctional component is not more than 100 mPa·s.

10. The method according to claim 3, wherein the polyfunctional component is selected from the group consisting of alkoxysilane, vinylsilane, thiolsilane, and halogen alkyl alkoxysilane.

11. The method according to claim 3, wherein a functional group of the polyfunctional component is an isocyanate group.

12. An article manufacturing method comprising:
forming a pattern of a curable composition on a substrate using a pattern forming method defined in claim 1;
processing the substrate with the pattern formed in the forming; and
manufacturing an article from the processed substrate.
